(19) United States
(12) Patent Application Publication
(10) Pub. No.: US 2025/0331284 A1
(43) Pub. Date: Oct. 23, 2025

(54) SEQUENTIAL SELF-ALIGNING METHOD IN COMPLEMENTARY FIELD EFFECT TRANSISTOR DEVICES

(71) Applicant: Applied Materials, Inc., Santa Clara, CA (US)

(72) Inventors: Balasubramanian PRANATHARTHIHARAN, Santa Clara, CA (US); Gregory COSTRINI, Flanders, NJ (US); Ashish PAL, San Ramon, CA (US); El Mehdi BAZIZI, San Anselmo, CA (US); He REN, San Jose, CA (US)

(21) Appl. No.: 19/094,489

(22) Filed: Mar. 28, 2025

Related U.S. Application Data
(60) Provisional application No. 63/637,344, filed on Apr. 22, 2024.

(51) Int. Cl. H10D 84/01; H10D 30/01; H10D 64/01

(52) U.S. Cl. CPC H10D 84/0186; H10D 64/017; H10D 84/0172; H10D 84/0188; H10D 30/0198

(57) ABSTRACT

Described are methods for forming complementary field-effect transistor (CFET), or other vertically aligned semiconductor structures, utilizing a sequential self-aligning process. In one example, a method of forming a complementary field-effect transistor (CFET) is provide. The method includes replacing top sacrificial layers interleaved between channel layers in a top superlattice of a top device structure with top replacement metal gate layers, the top device structure disposed on a bottom device structure, the bottom device structure disposed on a first substrate layer; securing a second substrate layer to the top device structure and removing the first substrate layer from the bottom device structure; and replacing bottom sacrificial layers interleaved between channel layers in a bottom superlattice of the bottom device structure with bottom replacement metal gate layers.

### RELATED APPLICATIONS

This application claims benefit from U.S. Provisional Application Ser. No. 63/637,344, filed Apr. 22, 2024, the contents of which is incorporated by reference in its entirety.

### BACKGROUND

### Field

Embodiments described herein generally relate to semiconductor device fabrication, and more particularly, to method for forming complementary field effect transistor (CFET) devices.

### Description of the Related Art

To continue scaling beyond the physical limit of planar metal oxide semiconductor field effect transistor (MOSFET), as well as quasi-planar devices such as Fin-FETs, and traditional, nanosheet, or forksheet, gate-all-around FETs (GAAFETs), complementary FET (CFET) devices have been proposed. The CFET is attractive for scaling down in technology nodes due to its vertically stacked NMOS and PMOS structure which offers significant advantages over other transistor types, including a reduction in area requirements and power usage.

However, the vertical orientation of CFET devices brings many production challenges. For example, in the currently proposed process flows, a contact trench in the bottom device is filled with silicide and metal contact plug prior to the formation of the top device. As a result, the silicide and the contact plug formed of currently known materials, such as titanium silicide, cobalt, or tungsten, may not withstand high temperature processes to form the top device and may degrade during the high temperature processes. The high temperature processes also cause issues with the front-side copper lines when the backside contacts are formed. In another example, the vertical orientation of CFET architecture creates very high-aspect ratio features that are difficult to create and to deposit material uniformly within. Accordingly, new methods of forming CFET devices are needed.

### SUMMARY

Embodiments of the present disclosure provide a method for forming a semiconductor device structure, and more particularly, to methods for forming complementary field effect transistor (CFET) devices, or other vertically aligned semiconductor structures, utilizing a sequential self-aligning process.

In one example, a method of forming a complementary field-effect transistor (CFET) is provide. The method includes replacing top sacrificial layers interleaved between channel layers in a top superlattice of a top device structure with top replacement metal gate layers, the top device structure disposed on a bottom device structure, the bottom device structure disposed on a first substrate layer; securing a second substrate layer to the top device structure and removing the first substrate layer from the bottom device structure; and replacing bottom sacrificial layers interleaved between channel layers in a bottom superlattice of the bottom device structure with bottom replacement metal gate layers.

In another example, a method forming a CFET includes sequentially forming a CFET device from a nanosheet stack disposed on a first substrate layer, wherein the nanosheet stack comprises a bottom device structure and a top device structure disposed over the bottom device structure, the bottom device structure and the top device structure each including: (a) a sacrificial superlattice layer, and (b) a superlattice disposed over the sacrificial superlattice layer, the superlattice comprising a plurality of channel layers extending through a dummy gate layer, wherein the plurality of channel layers are separated by a plurality of sacrificial layers, wherein the dummy gate layer includes a top dummy gate layer in the top device structure and a bottom dummy gate layer in the bottom device structure. Sequentially forming the CFET device further includes forming a portion of a bottom field effect transistor (FET) from the bottom device structure, and forming a portion of a top FET from the top device structure; replacing the sacrificial superlattice layer of the bottom device structure with an isolation structure, and replacing the sacrificial superlattice layer of the top device structure with an isolation structure; forming a second portion of the bottom FET from the bottom device structure, disposing a first dielectric fill layer over the bottom device structure; forming a second portion of the top FET; bonding a second substrate layer to the top FET; removing the first substrate layer; removing the first dielectric fill layer; forming a second portion of the bottom FET; forming bottom FET device contacts; bonding a third substrate layer to the bottom FET; and forming top FET device contacts.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a schematic top view of a multi-chamber processing system, according to embodiments described herein.

FIGS. 2A-2C illustrate a process flow diagram of a method for forming a semiconductor structure according to embodiments described herein.

FIGS. 3A-3Z illustrate cross sectional views of a portion of a semiconductor device substrate during a method according to embodiments described herein.

FIG. 4 illustrates a cross sectional view of a portion of a semiconductor device structure according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

The disclosure contains at least one page of the drawings executed in color. Copies of this disclosure with the color appendix will be provided to the Office upon request and payment of the necessary fee. As the color drawings are being filed electronically via EFS-Web, only one set of the drawings is submitted.

### DETAILED DESCRIPTION

Integrated circuits have evolved into complex devices that can include billions of transistors, capacitors, and resistors on a single chip. In the course of integrated circuit evolution, functional density (that is, the number of interconnected devices per chip area) has generally increased while geometry size (that is, the smallest component (or line) that can be created using a fabrication process) has decreased.

To continue scaling beyond the physical limit of planar metal oxide semiconductor field effect transistor (MOSFET), as well as quasi-planar devices such as Fin-FETs, and nanosheet and forksheet gate-all-around FETs (GAAFETs), complementary FET (CFET) devices have been proposed. The CFET is attractive for scaling down in technology nodes due to its vertically stacked NMOS and PMOS structures which offer significant advantages over other transistor types, including a reduction in area requirements and power usage.

However, the vertical orientation of CFET devices brings many production challenges. For example, in the currently proposed process flows, a contact trench in the bottom device is filled with silicide and metal contact plug prior to the formation of the top device. As a result, the silicide and the contact plug formed of currently known materials, such as titanium silicide, cobalt, or tungsten, may not withstand high temperature processes to form the top device and may degrade during the high temperature processes. The high temperature processes also cause issues with the front-side copper lines when the backside contacts are formed. In another example, the vertical orientation of CFET architecture creates very high-aspect ratio features that are difficult to create and deposit material uniformly within.

In contrast to a traditional monolithic approach, which relies on complicated alignment and device bonding methods which lower device performance and yields, aspects of the present disclosure include methods allowing for the creation of CFET, or other vertically aligned semiconductor structures, in a more efficient manner utilizing a sequential self-aligning process. The method described herein reduces problems with traditional high-aspect ratio features, by reducing feature height and eliminating several high-aspect ratio modules. Additionally, by inserting another insulator between the nanosheet stacks, the methods described herein, reduce, or eliminate, the requirement for high-temperature thermally stable silicides, contact liners, and gap fill materials allowing allow for current gate-all-around (GAA) replacement metal gate (RMG), and epitaxial, process to be utilized without requiring a lower thermal budget. For example, methods described herein also allow the front copper lines, which may fail at temperatures over 4000° C., to not be exposed to the backside contact formation thermal budget (≈800-850° C.).

### Processing System Example

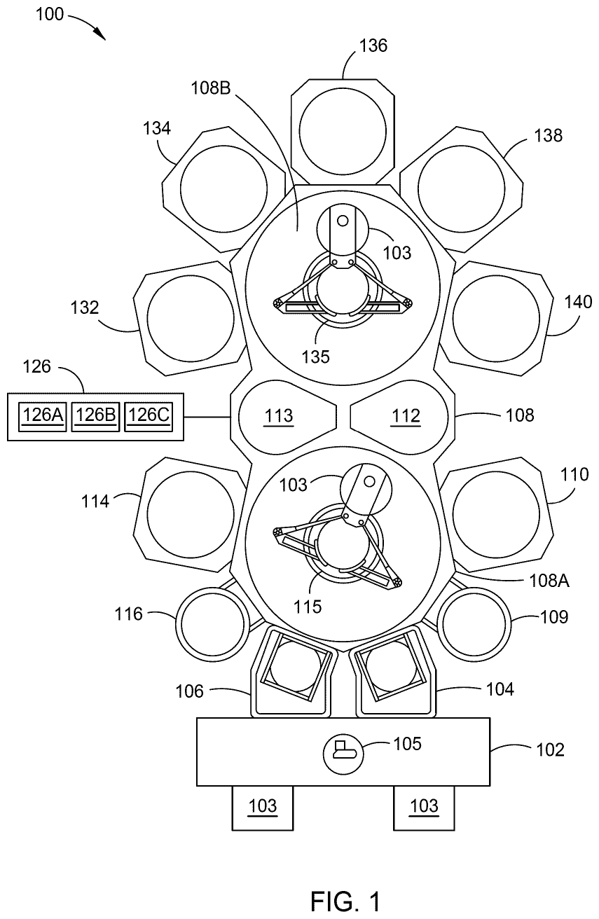

FIG. 1 illustrates a schematic representation of a processing system 100 for use with one or more embodiments of the disclosure. In one or more embodiments, the processing system 100 may be utilized to perform all or a portion of method 200.

As detailed below, substrates in the processing system 100 may be processed in and transferred between the various chambers without exposing the substrates to an ambient environment exterior to the processing system 100 (for example, an atmospheric ambient environment such as may be present in a fab). For example, the substrates may be processed in and transferred between the various chambers maintained at a low pressure (for example, less than or equal to about 300 Torr), or sub-atmospheric pressure, such as a vacuum environment, without breaking the reduced relative pressure or vacuum environment among various processes performed on the substrates in the processing system 100. Accordingly, the processing system 100 may provide for an integrated solution for some processing of substrates.

Examples of a processing system that may be suitably modified in accordance with the teachings provided include the Endura® integrated processing systems or other suitable processing systems commercially available from Applied Materials, Inc., located in Santa Clara, California (CA), United States of America. One may envision that other processing systems, including those from other manufacturers, may be adapted to benefit from aspects described.

FIG. 1 is a schematic top view of the processing system 100 (also referred to as a “processing platform”), according to embodiments described herein. The processing system 100 generally includes an equipment front-end module (EFEM) 102 for loading substrates into the processing system 100, a first load lock chamber 104 coupled to the EFEM 102, a transfer chamber 108 coupled to the first load lock chamber 104, and a plurality of other chambers coupled to the transfer chamber 108 as described in detail below. The EFEM 102 generally includes one or more robots 105 that are configured to transfer substrates from the front opening unified pods (FOUPs) 103 to at least one of the first load lock chamber 104 or the second load lock chamber 106. Proceeding counterclockwise around the transfer chamber 108 from the buffer portion 108A of the first load lock chamber 104, the processing system 100 includes a first dedicated degas chamber 109, a first pre-clean chamber 110, a first pass-through chamber 112, a second pass-through chamber 113, a second pre-clean chamber 114, a second degas chamber 116 and the second load lock chamber 106. The buffer portion 108A of the transfer chamber 108 includes a first robot 115 that is configured to transfer substrates to each of the load lock chambers 104, and 106, the degas chambers 109, and 116, the pre-clean chambers 110, and 114 and the pass-through chambers 112, and 113.

The back-end portion 108B of the transfer chamber 108 includes a second robot 135 that is configured to transfer substrates to each of the pass-through chambers 112, 113 and the processing chambers coupled to the back-end portion 108B of the processing system 100. The processing chambers can include a first processing chamber 132, a second processing chamber 134, a third processing chamber 136, a fourth processing chamber 138 and a fifth process chamber 140. In general, the processing chambers 132, 134, 136, 138, 140 can include at least one of an atomic layer deposition (ALD) chamber, chemical vapor deposition (CVD) chamber, physical vapor deposition (PVD) chamber, etch chamber, degas chamber, an anneal chamber, and other type of semiconductor substrate processing chamber. In some embodiments, one or more of the processing chambers 132, 134, 136, 138, 140 are a PVD chamber. In some examples, the processing chamber 110 may be capable of performing an etch process, the processing chamber 114 may be capable of performing a cleaning process or an annealing process, and the processing chambers 132, 134, 136, 138, 140 may be capable of performing respective CVD or ALD deposition processes. In one example, the processing chamber 110 or 114 may be a SELECTRA® Etch chamber available from Applied Materials of Santa Clara, Calif. In one example, the processing chamber 110 or 114 may be a SICONI® Pre-clean chamber available from Applied Materials of Santa Clara, Calif. In one example, the processing chambers 132, 134, 136, 138, or 140 may be a VOLTA® CVD/ALD chamber, or SIP ENCORE® PVD chambers available from Applied Materials of Santa Clara, Calif.

The buffer portion 108A and back-end portion 108B of the transfer chamber 108 and each chamber coupled to the transfer chamber 108 may be maintained at a vacuum state. As used herein, the term “vacuum” may refer to pressures less than 760 Torr, and will typically be maintained at pressures near 10⁻⁵ Torr (that is, ˜10⁻³ Pa). However, some high-vacuum systems may operate below near 10⁻⁷ Torr (that is, ˜10⁻⁵ Pa). In certain embodiments, the vacuum is created using a rough pump and/or a turbomolecular pump coupled to the transfer chamber 108 and to each of the one or more process chambers (for example, process chambers 109-140). However, other types of vacuum pumps are also contemplated.

A system controller 126, such as a programmable computer, is coupled to the processing system 100 for controlling one or more of the components therein. For example, the system controller 126 may control the operation of one or more of the processing chambers, such as processing chambers 132, 134, 136, 138, 140. In operation, the system controller 126 enables data acquisition and feedback from the respective components to coordinate processing in the processing system 100.

The system controller 126 includes a programmable central processing unit (CPU) 126A, which is operable with a memory 126B (for example, non-volatile memory) and support, circuits 126C. The support circuits 126C (for example, cache, clock circuits, input/output subsystems, power supplies, etc., and combinations thereof) are conventionally coupled to the CPU 126A and coupled to the various components within the processing system 100.

In some embodiments, the CPU 126A is one of any form of general-purpose computer processor used in an industrial setting, such as a programmable logic controller (PLC), for controlling various monitoring system component and sub-processors. The memory 126B, coupled to the CPU 126A, is non-transitory and is typically one or more of readily available memory such as random access memory (RAM), read only memory (ROM), floppy disk drive, hard disk, or any other form of digital storage, local or remote.

Herein, the memory 126B is in the form of a computer-readable storage media containing instructions (for example, non-volatile memory), that when executed by the CPU 126A, facilitates the operation of the processing system 100. The instructions in the memory 126B are in the form of a program product such as a program that implements the methods of the present disclosure (for example, middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (for example, read-only memory devices within a computer such as CD-ROM disks readable by a CD-ROM drive, flash memory, ROM chips or any type of solid-state non-volatile semiconductor memory) on which information is permanently stored; and (ii) writable storage media (for example, floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. The various methods disclosed herein may generally be implemented under the control of the CPU 126A by the CPU 126A executing computer instruction code stored in the memory 126B (or in memory of a particular processing chamber) as, for example, a software routine. When the computer instruction code is executed by the CPU 126A, the CPU 126A controls the chambers to perform processes in accordance with the various methods.

### Semiconductor Device Example

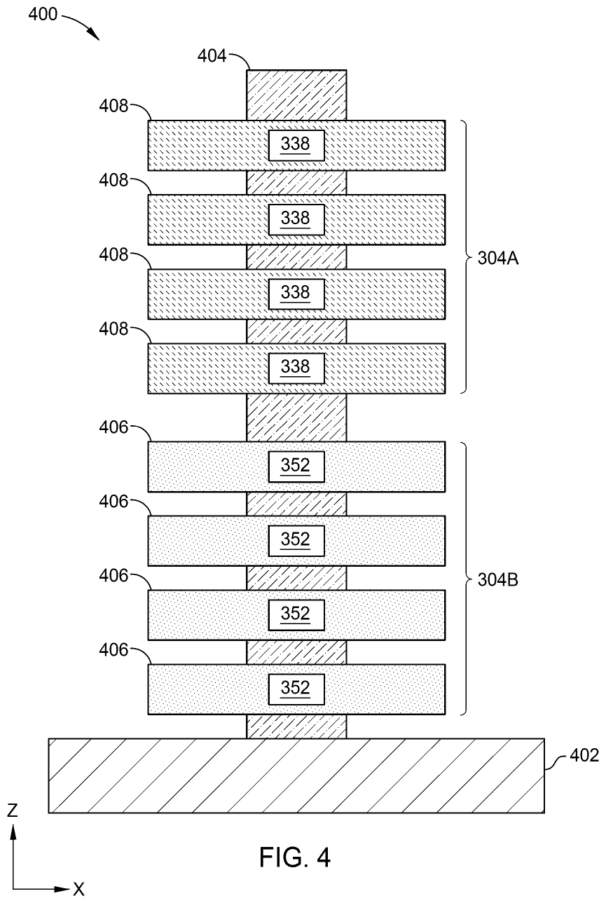

FIG. 4 illustrates a simplified cross sectional view of a portion of a semiconductor device structure according to one or more embodiments described herein. More specifically, the semiconductor device structure illustrated is of a CFET 400. In contrast to current transistor architectures which are largely planar or quasi-planar, the CFET utilizes a vertically stacked layout including an insulator 402, a bottom device structure 304B (e.g., a bottom FET) disposed above the insulator 402, a top device structure 304A (e.g., a top FET) disposed above the bottom device structure 304B, and a common gate 404 disposed through the bottom device structure 304B and the top device structure 304A. In this embodiment, the bottom device structure 304B is a PMOS device including several layers of p-type material 352 forming source/drain regions 406. The top device structure 304A is an NMOS device including several layers of n-type material 338 forming source/drain regions 408. In other embodiments, the top device structure 304A may be a PMOS device and the bottom device structure 304B may be an NMOS device.

### Processing Sequence Example

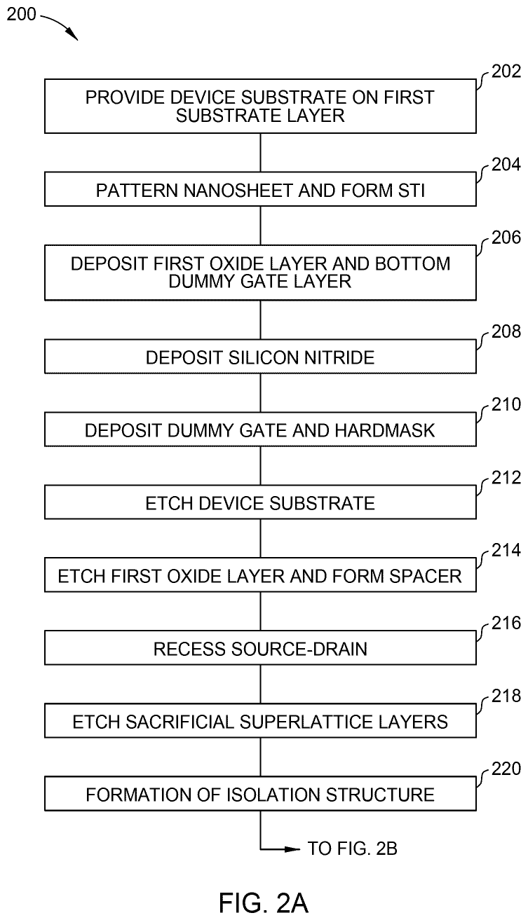

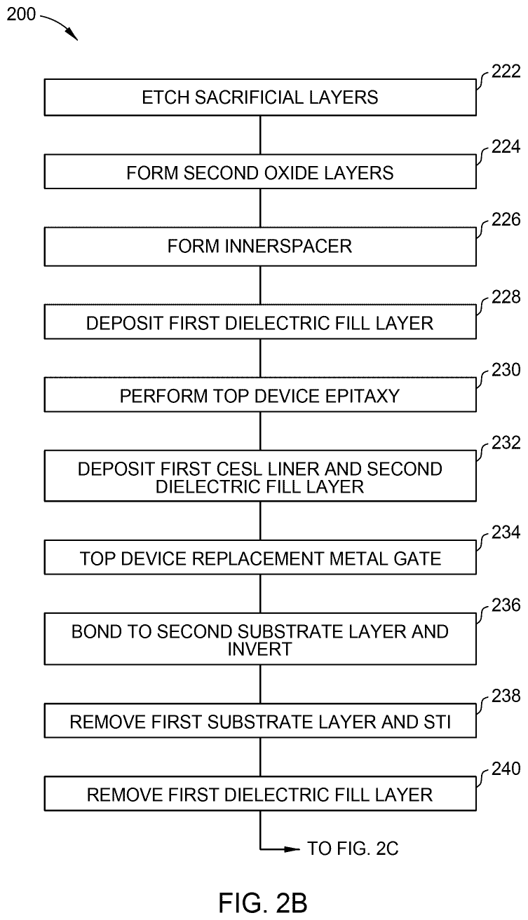

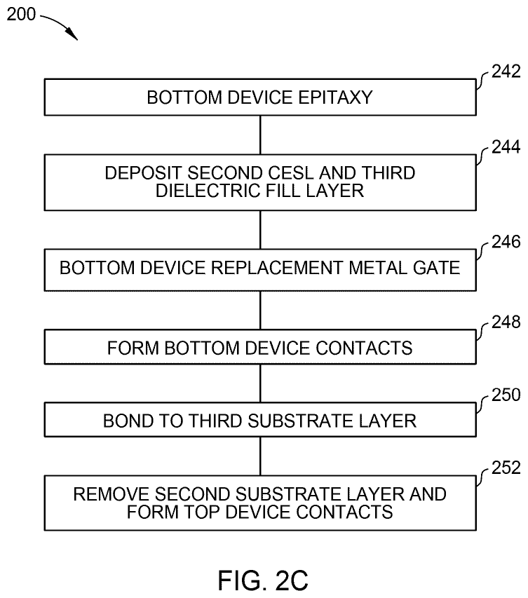

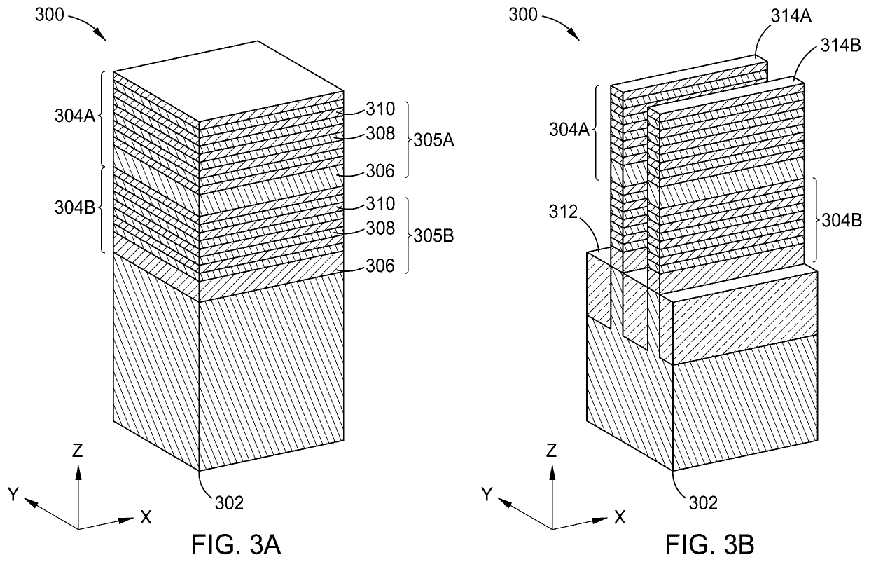

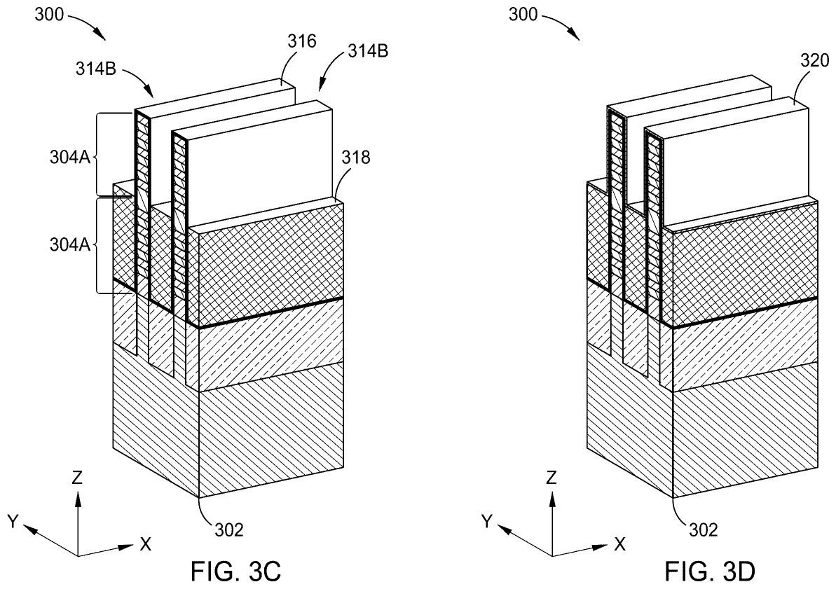

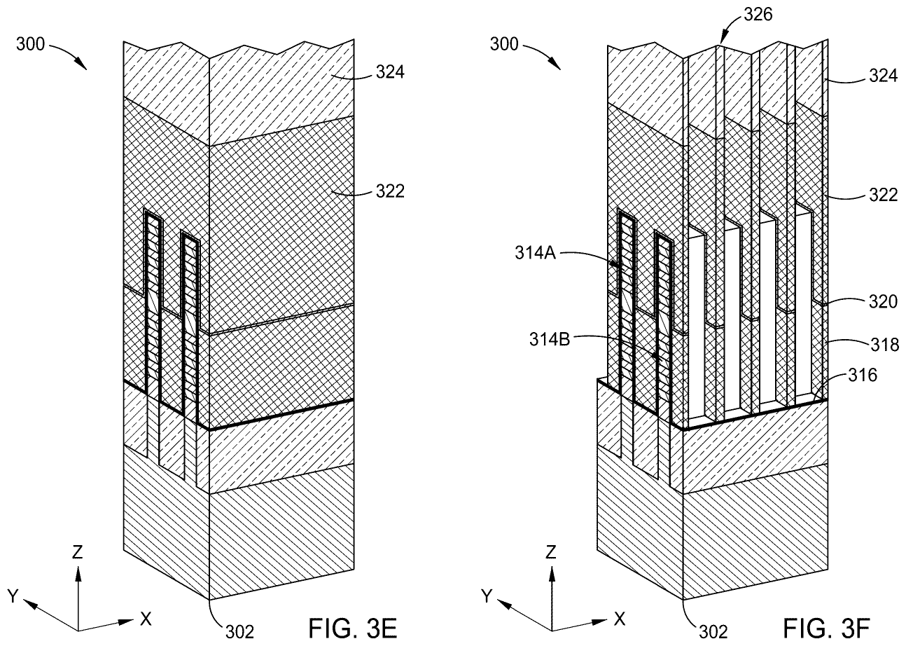

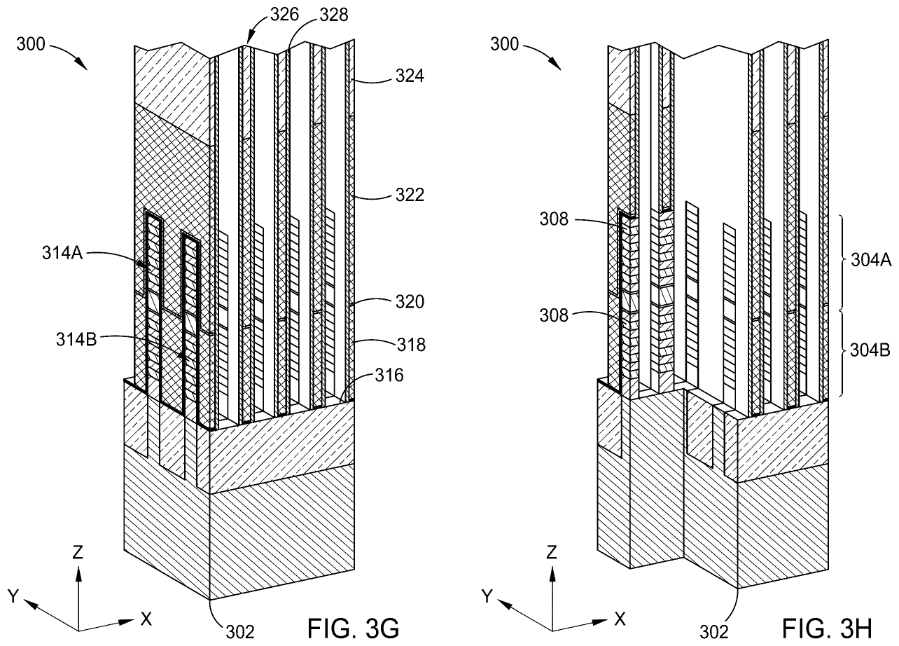

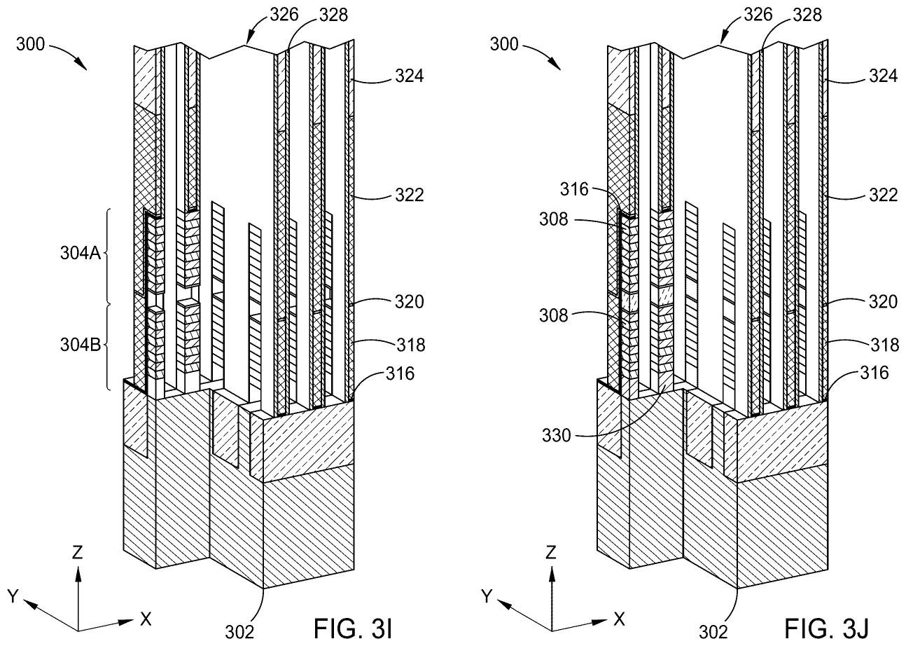

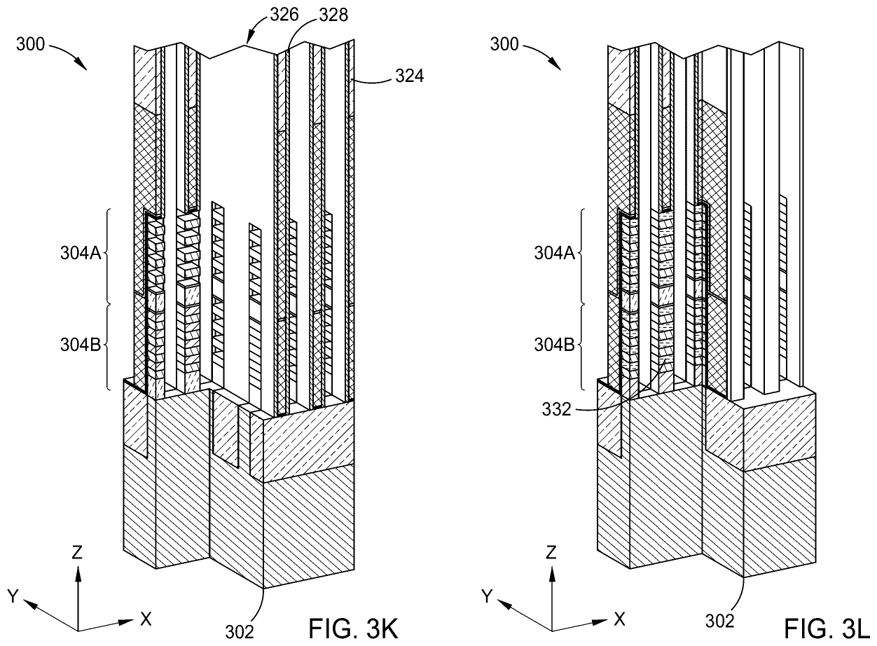

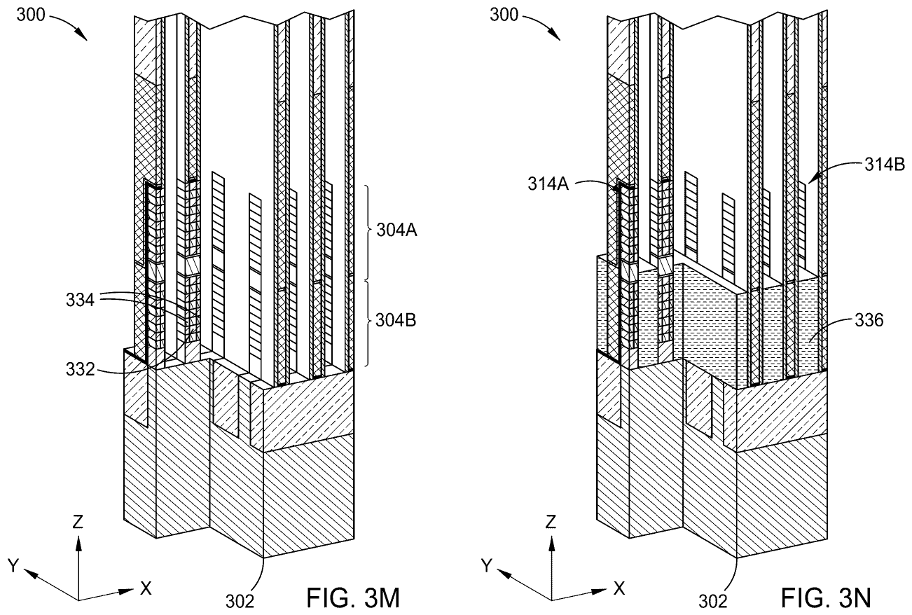

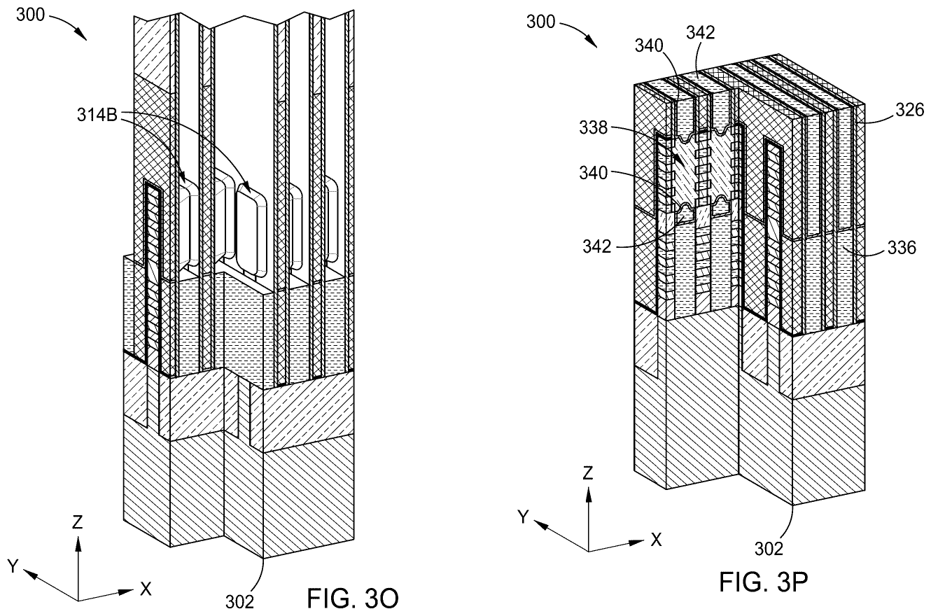

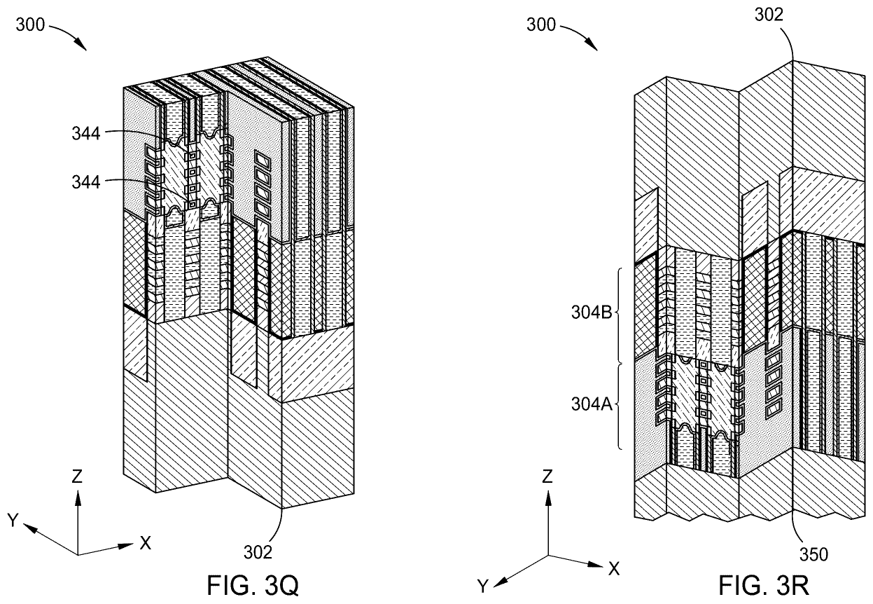

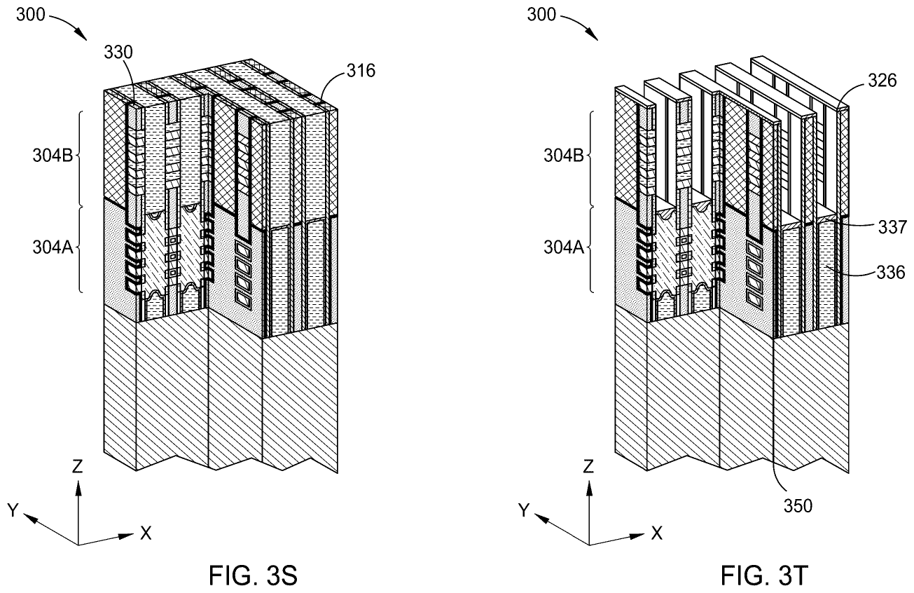

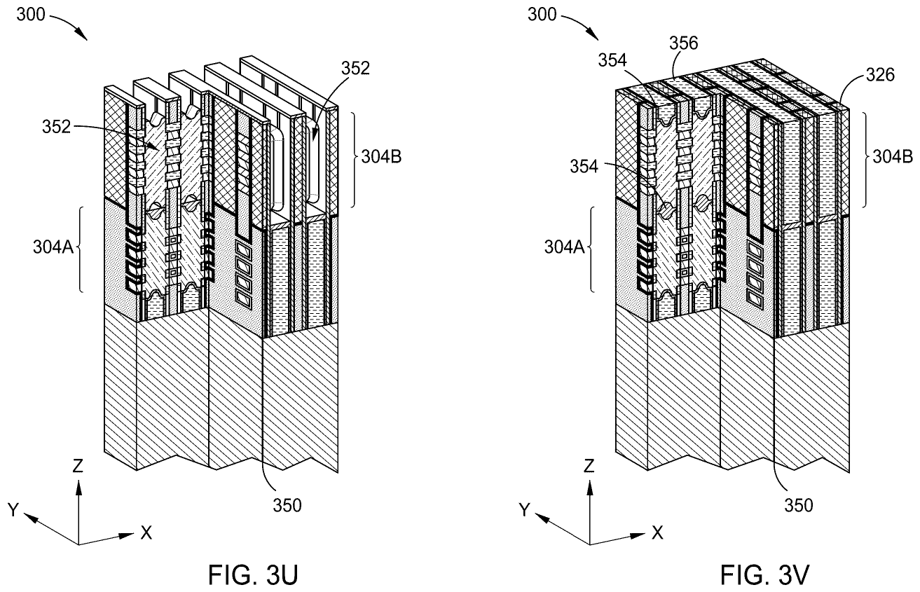

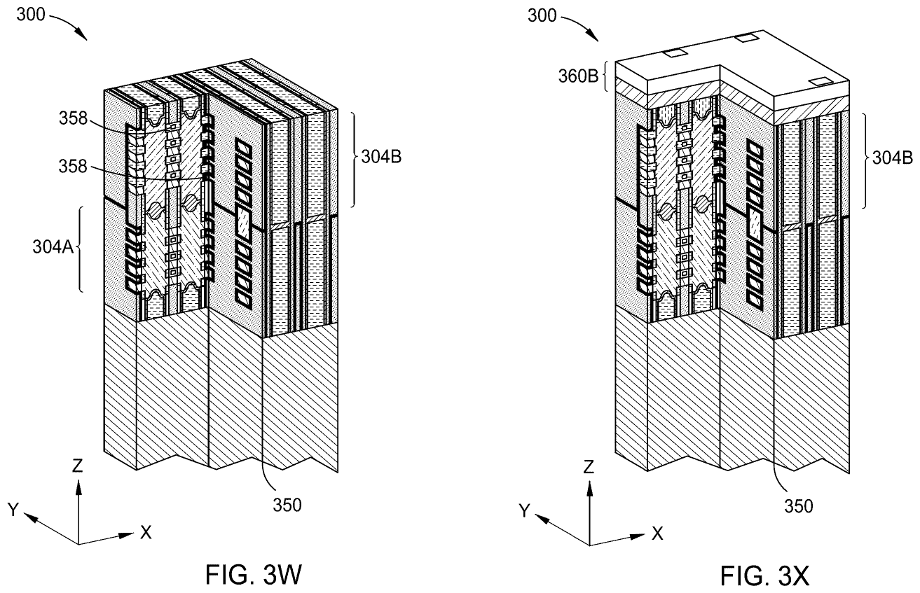

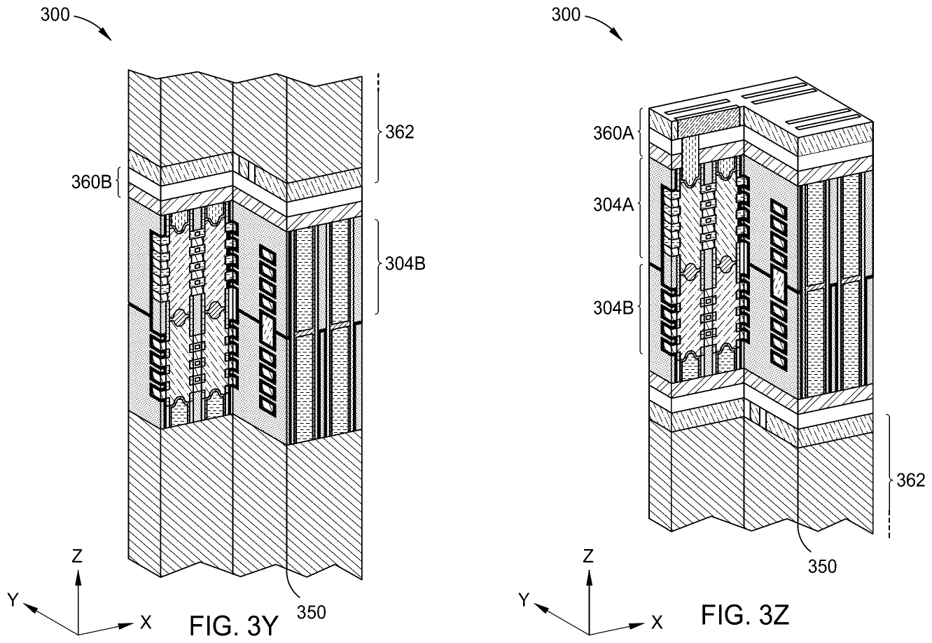

Building from the processing system 100 and information provided in FIGS. 1, 4, and 3A-3CC, embodiments of the disclosure include a method 200 of forming a CFET semiconductor device. A process flow diagram of method 200 is depicted in FIGS. 2A-2C. While method 200 is described using an example of a portion of a CFET, method 200 is not limited to a specific transistor type or construction. Further, FIGS. 3A-3CC only illustrate a portion of a device substrate 300. In practice, additional layers and structures may be disposed above, below, or within those depicted in FIGS. 3A-3CC.

At operation 202 of method 200, a device substrate 300 is transferred to a processing chamber. FIG. 3A illustrates a cross-sectional view of a portion of the device substrate 300. The device substrate 300 includes a first substrate layer 302, a bottom device structure 304B disposed above the first substrate layer 302, and a top device structure 304A disposed above the bottom device structure 304B. The first substrate layer 302 is a temporary substrate, as it is removed later in the fabrication sequence.

The device substrate 300 includes a first substrate layer 302. The term “substrate” as used herein refers to a layer of material that serves as a basis for subsequent processing operations and includes a surface to be cleaned. The first substrate layer 302 may be a silicon-based material or any suitable insulating materials or conductive materials as needed. The first substrate layer 302 may include a material such as, but not limited to, crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

The device substrate 300 includes double a bottom device structure 304B disposed above the first substrate layer 302 and a top device structure 304A disposed above the bottom device structure 304B. The top device structure 304A and the bottom device structure 304B each include a sacrificial superlattice layer 306 with a superlattice disposed above. The top superlattice 305A of the top device structure 304A, and the superlattice 305B of the bottom device structure 304B, each include alternating layers of the channel layer 308 and the sacrificial layer 310 stacked in the Z-direction disposed above each respective sacrificial superlattice layer 306. The top superlattice 305A of the top device structure 304A, and the superlattice 305B of the bottom device structure 304B, may each have between about 2 pair and about 10 pairs of the channel layer 308 and the sacrificial layer 310. The top superlattice 305A of the top device structure 304A, and the superlattice 305B of the bottom device structure 304B, may each optionally have between more than 10 pairs of the channel layer 308 and the sacrificial layer 310.

The channel layer 308 may be formed of a first material. The sacrificial layer 310 may be formed of a second material. The sacrificial superlattice layer 306 may be formed of a third material. The sacrificial superlattice layer 306 may be formed from a single layer of material, or alternatively, multiple layers of material. The etch selectivity of the second material (i.e., the ratio of the etch rate of the second material to the etch rate of the first material) is between about 10:1 to about 500:1. Examples of the first material include, but are not limited to, pure silicon (Si), germanium (Ge), and silicon germanium (SiGe). Examples of the second material include, but are not limited to, SiGe having a Ge concentration between about 10% and about 30%. The third material may be formed of a material that has an etch selectivity from the first material and the second material is between about 10:1 to about 200:1. Examples of the third material include, but are not limited to, SiGe having a higher Ge concentration between about 35% and about 60%.

The channel layers 308 each have a thickness of between about 5 nm and about 40 nm. The sacrificial layers 310 each have a thickness of between about 5 nm and about 40 nm. The superlattice sacrificial layer 306 may have a thickness of between about 20 nm and about 100 nm.

The sacrificial superlattice layer 306, the channel layer 308, and the sacrificial layers 310 of the bottom device structure 304B and the top device structure 304A may be formed by any suitable deposition process including, but not limited to PVD, CVD, and ALD. For example, via epitaxy. Forming the sacrificial superlattice layer 306, and the alternating pattern of the channel layers 308 and sacrificial layers 310, of the bottom device structure 304B by epitaxy generally includes positioning the device substrate 300 on a substrate support in a processing volume of a processing chamber, heating the first substrate layer 302 to a target temperature, and flowing one or more precursor gases into the processing volume. The precursor gas is selected dependent upon the specific materials and process involved. In one embodiment, the precursor gases may include silane (SiH₄) and germane (GeH₄). When heated, the precursor gases decompose and deposit onto the substrate surface first by nucleation, then growth of the crystal lattice structure. By controlling the growth conditions, including temperature, pressure, and precursor gas composition, the proprieties of the resulting epitaxial layer can be controlled.

The top device structure 304A includes the sacrificial superlattice layer 306 formed above the bottom device structure 304B. The top device structure 304A includes an alternating pattern of layers including a channel layer 308, and a sacrificial layer 310, formed above the sacrificial superlattice layer 306 of the top device structure 304A. The top device structure 304A may be formed by any suitable process, as described above.

At operation 204 of method 200, the top device structure 304A, and bottom device structure 304B are etched, and shallow trench isolation (STI) features 312 are formed. FIG. 3B illustrates the device substrate 300 after operation 204 of method 200. In operation 204 of method 200, etching the device substrate 300 includes first forming and patterning a resist layer above the top device structure 304A.

Forming the resist layer may be performed by any suitable lithography process. For example, the resist layer may be formed using an optical lithography process, an extreme ultraviolet (EUV) lithography process, x-ray lithography process, an electron beam lithography process, a nanoimprint lithography process, a step and flash imprint lithography process, maskless lithography process, or similar process. The areas of the device substrate 300 covered by the developed resist layer are protected from subsequent etching operations.

Following the forming and patterning of the resist layer, the device substrate 300 is subjected to an etching process. In one embodiment, the etching process is a reactive ion etching (RIE) process. During the RIE process, the processing chamber operates at a vacuum pressure. The vacuum pressure is between about 2 Torr to about 10−6 Torr. A non-reactive gas (e.g., argon), and an etching gas (e.g., a reactive gas typically containing chlorine (Cl) or fluorine (F)), are introduced into the processing chamber. An electromagnetic field ionizes these gases, creating a plasma of ions, electrons, and neutral particles. Positively charged ions are accelerated towards the substrate, where they collide with the device substrate 300 surface, physically sputtering material from the device substrate 300. Meanwhile, the reactive gas molecules chemically react with the exposed material, forming byproducts which are removed. Both the sputtering and chemical reactions enable for precise removal of material not protected by the resist layer. In other embodiments, a different dry etching process, a wet etching process, or combination of processes, may be utilized.

After the etching process, the remaining resist layer is removed. Removal of the remaining resist layer may be accomplished through a dry stripping process or a wet stripping process. The dry stripping process may include etching the resist layer. A plasma of reactive gases is used to react with and remove the resist layer. The high-energy ions and radicals in the plasma break the resist material into volatile byproducts, which are pumped away. The dry stripping process may be highly selective, only removing the resist layer, or less selective to additionally remove underlying layers. A wet stripping process may include use of a chemical solvent, or combination of solvents, depending on the type of resist material used. Example solvents include, but are not limited to, acetone, N-methyl-2-pyrrolidone (NMP), gamma-butyrolactone (GBL), and other suitable solvents.

The STI features 312 may be formed by any suitable process. The STI features 312 may be formed before the etching process described above or after the etching process. The STI features 312 may reduce interference by reducing parasitic capacitance and crosstalk between neighboring transistors. This may allow for higher packing densities and improved performance. The STI features 312 are formed of any suitable dielectric material. For example, the STI features 312 may include, but are not limited to silicon dioxide, silicon nitride, silicon oxynitride, high-k materials, polysilicon, spin-on glass, boron phosphosilicate glass, or combinations thereof.

At the end of operation 204, as shown in FIG. 3B a first structure 314A and a second structure 314B, each including a top device structure 304A and bottom device structure 304B, and each separated by the STI features 312, remain.

At operation 206 of method 200, a first oxide layer 316, and a bottom dummy gate layer 318 are formed. FIG. 3C illustrates the device substrate 300 after operation 206 of method 200. The first oxide layer 316 is disposed above the STI features 312, above the first structure 314A and the second structure 314B, and over the sidewall surfaces of the first structure 314A and the second structure 314B. The first oxide layer 316 acts as a sacrificial, or “dummy” oxide, layer for subsequent operations. The first oxide layer 316 may be formed of any suitable dielectric material. For example, the first oxide layer 316 may include, but is not limited to silicon dioxide, silicon nitride, silicon oxynitride, high-k materials, polysilicon, spin-on glass, boron phosphosilicate glass, or combinations thereof. The first oxide layer 316 may be formed by any suitable deposition process, including, but not limited to, physical vapor deposition (PVD), chemical vapor deposition (CVD), atomic layer deposition (ALD), or any combination thereof. The deposition process may include intermediary steps such as cleaning, degassing, lithography, etching, chemical-mechanical polishing (CMP), or other processes common to semiconductor device manufacturing.

The device substrate 300 includes a bottom dummy gate layer 318 disposed above the first oxide layer 316. The bottom dummy gate layer 318 extends from the first oxide layer 316 disposed above the STI features 312 to between about the top device structure 304A and the bottom device structure 304B on both the first structure 314A and the second structure 314B. The bottom dummy gate layer 318 may include, but is not limited to, polysilicon. The bottom dummy gate layer 318 may be formed by any suitable deposition process including, but not limited to, PVD, CVD, ALD, or combinations thereof. The deposition process may include intermediary steps such as cleaning, degassing, lithography, etching, CMP, or other processes common to semiconductor device manufacturing.

As illustrated in FIG. 3D, at operation 208 of method 200, a silicon nitride layer 320 is disposed over the exposed portions of the device substrate 300. The silicon nitride layer 320 may include, but is not limited to, silicon nitride (Si₃N₄). The silicon nitride layer 320 may be formed by any suitable deposition process including, but not limited to, PVD, CVD, ALD, or combinations thereof. The deposition process may include intermediary steps such as cleaning, degassing, lithography, etching, CMP, or other processes common to semiconductor device manufacturing.

As illustrated in FIG. 3E, at operation 210 of method 200, a top dummy gate layer 322, and hardmask layer 324 are formed. The device substrate 300 includes the top dummy gate layer 322 disposed above the silicon nitride layer 320. The top dummy gate layer 322 extends from the silicon nitride layer 320 to, or above, the silicon nitride layer disposed above the top device structure 304A on both the first structure 314A and the second structure 314B. The top dummy gate layer 322 may include, but is not limited to, polysilicon. The top dummy gate layer 322 may be formed by any suitable deposition process including, but not limited to, PVD, CVD, ALD, or combinations thereof. The deposition process may include intermediary steps such as cleaning, degassing, lithography, etching, CMP, or other processes common to semiconductor device manufacturing.

The device substrate 300 includes the hardmask layer 324 disposed above the top dummy gate layer 322. Forming the hardmask layer 324 layer may be performed by any suitable deposition process. For example, PVD, CVD, ALD, or combinations thereof. Once deposited, the hardmask layer 324 is patterned to form a “dummy gate hardmask” or “dummy gate hardmask feature”. For example, the hardmask layer 324 may be patterned using an optical lithography process, an extreme ultraviolet (EUV) lithography process, x-ray lithography process, an electron beam lithography process, a nanoimprint lithography process, a step and flash imprint lithography process, maskless lithography process, or similar process. The areas of the device substrate 300 covered by the developed and patterned hardmask layer 324 are protected from subsequent etching operations. Forming the patterned hardmask layer 324 process may include intermediary steps such as cleaning, degassing, lithography, etching, CMP, or other processes common to semiconductor device manufacturing.

At operation 212 of method 200, the device substrate 300 is subjected to an etching process to remove the portions of the device substrate 300 not protected by the patterned hardmask layer 324. In this embodiments, the portions of the device substrate 300 removed include portions of the top dummy gate layer 322, the silicon nitride layer 320, and the bottom dummy gate layer 318, stopping at the first oxide layer 316.

Removal of the portions of the top dummy gate layer 322, the silicon nitride layer 320, and the bottom dummy gate layer 318, may be accomplished through a dry etching process, a wet etching process, or a CMP process. The dry etching process may include plasma etching the device substrate 300. During the dry etching process, a plasma of reactive gases is used to react with and remove portions of the top dummy gate layer 322, the silicon nitride layer 320, and the bottom dummy gate layer 318. The reactive gases used in the dry etching process typically include fluorine-based compounds. The high-energy ions and radicals in the plasma break the top dummy gate layer 322, the silicon nitride layer 320, and the bottom dummy gate layer 318, into volatile byproducts, which are pumped away. The dry etching process may be highly selective, only removing small portions of the top dummy gate layer 322, the silicon nitride layer 320, and the bottom dummy gate layer 318, or less selective to additional material. The dry etching process may include reactive ion etching (RIE), inductively coupled plasma (ICP), capacitively coupled plasma (CCP), or other suitable dry etching process. The device substrate 300, after operation 212 of method 200, is illustrated in FIG. 3F. The etching process of operation 212 of method 200 leaving vertical structures 326, separated by high-aspect ratio trenches, running perpendicular to the first structure 314A and the second structure 314B.

At operation 214 of method 200, the device substrate 300 is exposed to an etching process to remove the exposed first oxide layer 316 disposed between the vertical structures 326, followed by forming a spacer layer 328. Etching the first oxide layer 316 of the device substrate 300 may be accomplished through a dry etching process, a wet etching process. The dry etching process may include plasma etching the device substrate 300. During the dry etching process, a plasma of reactive gases is used to react with and remove the exposed portions of first oxide layer 316 above the STI features 312, above the first structure 314A and the second structure 314B, and the side surfaces of the first structure 314A and the second structure 314B. The reactive gases used in the dry etching process typically include fluorine-based compounds. The high-energy ions and radicals in the plasma break the first oxide layer 316 into volatile byproducts, which are pumped away. The dry etching process may be highly selective, only removing small portions of the first oxide layer 316, or less selective to remove additional. The dry etching process may include reactive ion etching (RIE), inductively coupled plasma (ICP), capacitively coupled plasma (CCP), or other suitable dry etching process.

After the etching process, operation 214 of method 200 includes disposing a conformal spacer layer 328 on the exposed side surfaces of the vertical structures 326. The spacer layer may be formed of any suitable material including, but not limited to, silicon dioxide (SiO2), silicon nitride (Si3N4), organosilicate glass (OSG), fluorinated silicate glass (FSG), Black Diamond®, organic dielectrics, low-k dielectrics, or combinations thereof. Deposition of the spacer layer 328 may be performed by any suitable deposition process including, but not limited to, PVD, CVD, ALD, or combinations thereof. The deposition process may include intermediary steps such as cleaning, degassing, lithography, etching, CMP, or other processes common to semiconductor device manufacturing. After depositing the conformal spacer layer 328, an high-energy RIE etch is performed to form the spacer structure, as depicted in FIG. 3G.

At operation 216 of method 200, the source-drain regions (i.e. the channel layers 308) of the top device structure 304A and the bottom device structure 304B are recessed. Recessing the superlattice material stack comprised of channel layers 308, layers 306 and layers 310 depicted as 304A and 304B in FIG. 3A to form the source-drain recess depicted in FIG. 3H. By recessing the source-drain areas, the performance of the transistor, particularly in terms of controlling the flow of charge carrier may be enhanced. Reasons for the improved performance may include mitigating short-channel effects and reducing parasitic capacitance. Recessing the source-drain regions of the device substrate 300 includes modifying the topography in the channel layers 308 by selectively removing a portion of the first material in the channel layers 308. The process of creating the source-drain recess includes selective etching a portion of the channel layers 308 by any suitable dry etching process, wet etching process, or any combination, as described above. The device substrate 300, after operation 216 of method 200, is depicted in FIG. 3H.

At operation 218 of method 200, the device substrate 300 is exposed to an etching process to remove the sacrificial superlattice layer 306. Etching the sacrificial superlattice layer 306 of the device substrate 300 may be accomplished through a dry etching process, a wet etching process, or a combination of processes. The dry etching process may include plasma etching the device substrate 300. During the dry etching process, a plasma of reactive gases is used to react with and remove the SiGe layer 306 from the top device structure 304A and the bottom device structure 304B. The reactive gases used in the dry etching process typically include fluorine-based compounds. The high-energy ions and radicals in the plasma break the sacrificial superlattice layer 306 into volatile byproducts, which are pumped away. The dry etching process may be highly selective, only removing small portions of the sacrificial superlattice layer 306, or less selective to remove additional. The dry etching process may include reactive ion etching (RIE), inductively coupled plasma (ICP), capacitively coupled plasma (CCP), or other suitable dry etching process. The wet etching process may include cleaning the device substrate 300, masking portions of the device substrate 300, immersion in an etchant, cleaning, and mask removal. Examples of the etchant used in the wet etching process may include, but are not limited to, potassium hydroxide (KOH), tetramethylammonium hydroxide (TMAH), hydrofluoric acid (HF), buffered oxide etchants such as a mixture of ammonium fluoride (NH₄F) and HF, phosphoric acid (H₃PO₄) nitric acid (HNO₃), acetic acid (CH₃COOH), hydrochloric acid (HCl), ammonium persulfate (NH₄S₂O₈), ferric chloride (FeCl₃), cupric chloride (CuCl₂), acetone, hydrogen peroxide (H₂O₂), deionized water, or any combination thereof. The specific etchant used a wet etching process will depend on the material to be etched. When exposed to the etchant, the material being etched is dissolved into the solution, which is then removed leaving behind the etched pattern. The device substrate 300, after operation 216 of method 200, is depicted in FIG. 31.

At operation 220 of method 200, as depicted in FIG. 3J includes forming isolation structures 330 in the voids left by removing the sacrificial superlattice layer 306 in operation 218. The isolation structures 330 may be formed of any suitable dielectric material including, but not limited to, silicon dioxide, silicon nitride, silicon oxynitride, high-k materials, polysilicon, spin-on glass, boron phosphosilicate glass, or combinations thereof. Deposition of the isolation structures 330 may be performed by any suitable deposition process including, but not limited to, PVD, CVD, ALD, or combinations thereof. The deposition process may include intermediary steps such as cleaning, degassing, lithography, etching, CMP, or other processes common to semiconductor device manufacturing. The device substrate 300, after operation 224 of method 200, is depicted in FIG. 3J.

At operation 222 of method 200, the device substrate 300 is exposed to an etching process to remove the sacrificial layer 310. Etching the sacrificial layer 310 of the device substrate 300 may be accomplished through a dry etching process, a wet etching process. The dry etching process may include plasma etching the device substrate 300. During the dry etching process, a plasma of reactive gases is used to react with and remove the sacrificial layers 310 from the top device structure 304A and the bottom device structure 304B. The reactive gases used in the dry etching process typically include fluorine-based compounds. The high-energy ions and radicals in the plasma break the sacrificial layer 310 into volatile byproducts, which are pumped away. The dry etching process may be highly selective, only removing small portions of the sacrificial layer 310, or less selective to remove additional. The dry etching process may include reactive ion etching (RIE), inductively coupled plasma (ICP), capacitively coupled plasma (CCP), or other suitable dry etching process. The wet etching process may include cleaning the device substrate 300, masking portions of the device substrate 300, immersion in an etchant, cleaning, and mask removal. Examples of the etchant used in the wet etching process may include, but are not limited to, potassium hydroxide (KOH), tetramethylammonium hydroxide (TMAH), hydrofluoric acid (HF), buffered oxide etchants such as a mixture of ammonium fluoride (NH₄F) and HF, phosphoric acid (H₃PO₄) nitric acid (HNO₃), acetic acid (CH₃COOH), hydrochloric acid (HCl), ammonium persulfate (NH₄S₂O₈), ferric chloride (FeCl₃), cupric chloride (CuCl₂), acetone, hydrogen peroxide (H₂O₂), deionized water, or any combination thereof. The specific etchant used a wet etching process will depend on the material to be etched. When exposed to the etchant, the material being etched is dissolved into the solution which is then removed leaving behind the etched pattern. The device substrate 300, after operation 222 of method 200, is depicted in FIG. 3K.

At operation 224 of method 200, as illustrated in FIG. 3L, includes forming a second oxide layer 332 in the voids left by removing the sacrificial layer 310 in operation 222. The second oxide layer 332 acts as a sacrificial, or “dummy” oxide, layer for subsequent operations. The second oxide layer 332 may be formed of any suitable dielectric material. For example, the second oxide layer 332 may include, but is not limited to silicon dioxide, silicon nitride, silicon oxynitride, high-k materials, polysilicon, spin-on glass, boron phosphosilicate glass, or combinations thereof. The second oxide layer 332 may be formed by any suitable deposition process, including, but not limited to, physical vapor deposition (PVD), chemical vapor deposition (CVD), atomic layer deposition (ALD), or any combination thereof. The deposition process may include intermediary steps such as cleaning, degassing, lithography, etching, chemical-mechanical polishing (CMP), or other processes common to semiconductor device manufacturing. The deposition process may include intermediary steps such as cleaning, degassing, lithography, etching, CMP, or other processes common to semiconductor device manufacturing.

At operation 226 of method 200, an inner spacer 334 is formed. Forming the inner spacer 334 includes, among other processes, an etching process, and a deposition process. The etching process includes removing a portion of the second oxide layer 332. Etching the portion of the second oxide layer 332 may be accomplished through a dry etching process, a wet etching process. The dry etching process may include plasma etching the device substrate 300. During the dry etching process, a plasma of reactive gases is used to react with and remove the portion of the second oxide layer 332. The reactive gases used in the dry etching process typically include fluorine-based compounds. The high-energy ions and radicals in the plasma break the portion of the second oxide layer 332 into volatile byproducts, which are pumped away. The dry etching process may be highly selective, only removing small portions of the second oxide layer 332, or less selective to remove additional. The dry etching process may include reactive ion etching (RIE), inductively coupled plasma (ICP), capacitively coupled plasma (CCP), or other suitable dry etching process. The wet etching process may include cleaning the device substrate 300, masking portions of the device substrate 300, immersion in an etchant, cleaning, and mask removal. Examples of the etchant used in the wet etching process may include, but are not limited to, potassium hydroxide (KOH), tetramethylammonium hydroxide (TMAH), hydrofluoric acid (HF), buffered oxide etchants such as a mixture of ammonium fluoride (NH₄F) and HF, phosphoric acid (H₃PO₄) nitric acid (HNO₃), acetic acid (CH₃COOH), hydrochloric acid (HCl), ammonium persulfate (NH₄S₂O₈), ferric chloride (FeCl₃), cupric chloride (CuCl₂), acetone, hydrogen peroxide (H₂O₂), deionized water, or any combination thereof. The specific etchant used a wet etching process will depend on the material to be etched. When exposed to the etchant, the material being etched is dissolved and becomes part the solution which is then removed leaving behind the etched pattern.

Following removal of the portion of the second oxide layer 332, the inner spacer 334 is disposed in the voids left by removing the portion of the second oxide layer 332. The inner spacer 334 may be formed by any suitable deposition process, including, but not limited to, physical vapor deposition (PVD), chemical vapor deposition (CVD), atomic layer deposition (ALD), or any combination thereof. The deposition process may include intermediary steps such as cleaning, degassing, lithography, etching, chemical-mechanical polishing (CMP), or other processes common to semiconductor device manufacturing. The deposition process may include intermediary steps such as cleaning, degassing, lithography, etching, CMP, or other processes common to semiconductor device manufacturing. The device substrate 300, after operation 226 of method 200, is depicted in FIG. 3M.

At operation 228 of method 200, a first dielectric fill layer 336 is disposed in between the vertical structures 326, in the high-aspect ratio trenches, running perpendicular to the first structure 314A and the second structure 314B, covering the bottom device structure 304B. The first dielectric fill layer 336 may be formed of any suitable dielectric material. For example, the first dielectric fill layer 336 may include, but is not limited to silicon dioxide, silicon nitride, silicon oxynitride, high-k materials, polysilicon, spin-on glass, boron phosphosilicate glass, or combinations thereof. The first dielectric fill layer 336 may be formed by any suitable deposition process, including, but not limited to, physical vapor deposition (PVD), chemical vapor deposition (CVD), atomic layer deposition (ALD), or any combination thereof. The deposition process may include intermediary steps such as cleaning, degassing, lithography, etching, chemical-mechanical polishing (CMP), or other processes common to semiconductor device manufacturing. The device substrate 300, after operation 228 of method 200, is depicted in FIG. 3N.

At operation 230 of method 200, an n-type material 338 is formed over the top device structure 304A. The n-type material 338 is formed via an epitaxy process. Epitaxy generally includes positioning the device substrate 300 on a substrate support in a processing volume of a processing chamber, heating the device substrate 300 to a target temperature, and flowing one or more precursor gases into the processing volume. The precursor gas is selected dependent upon the specific materials and process involved. In one embodiment, the precursor gases may include, but are not limited to, silane (SiH₄), disilane (Si₂H₆), tetrasilane (Si₄H₁₀), germane (GeH₄), digermane (Ge₂H₆), germanium tetrachloride (GeCl₄), trimethylgallium gallium Ga(CH₃)₃, phosphine (PH₃), phosphorus trichloride (PCl₃), triisobutylphosphine ([(CH₃)₃C]₃P), arsenic trichloride (AsCl₃), tertiarybutylarsine (AsC₄H₁₁), antimony trichloride (SbCl₃), or Sb(C₂H₅)₅, arsine (AsH₃), diborane (B₂H₆), trimethylphosphine (TMP), or any dopant or precursor common to semiconductor device manufacturing. When heated, the precursor gases decompose and deposit onto the substrate surface first by nucleation, then growth of the crystal lattice structure. By controlling the growth conditions, including temperature, pressure, and precursor gas composition, the proprieties of the resulting epitaxial layer can be controlled. In some embodiments with p-type device on top, instead of an n-type semiconductor, a p-type semiconductor may be formed in the location of the n-type material 338. The device substrate 300, after operation 230 of method 200, is depicted in FIG. 3O.

At operation 232 of method 200, a first contact etch stop liner (CESL) 340 is formed, and a second dielectric fill layer 342 is disposed. A chemical mechanical polishing process is performed after the second dielectric fill layer 342 is deposited to remove the excess deposited materials, planarize the surface, and expose the dummy gate material of vertical structures 326. The device substrate 300, after operation 232 of method 200, is depicted in FIG. 3P. The first CESL 340 is disposed on the exposed surfaces of the device substrate 300 including the side surfaces of the vertical structures 326, the top surface of the first dielectric fill layer 336, exposed surfaces of the first oxide layer 316, and exterior surfaces of the n-type material 338. The first CESL 340 is a thin layer of material designed to serve as a stop layer during later etching processes. The first CESL 340 may be formed of any suitable material including, but not limited to, silicon nitride, silicon-rich silicon nitride, or any combination thereof. Forming the first CESL 340 may be performed by any suitable deposition process, including, but not limited to, CVD, PVD, ALD, or any combination thereof. The deposition process may include intermediary steps such as cleaning, degassing, lithography, etching, CMP, or other processes common to semiconductor device manufacturing.

Following the first CESL 340, a second dielectric fill layer 342 is disposed over the device substrate 300 filling the remaining areas between the vertical structures 326, covering the n-type material 338 of the top device structure 304A. The second dielectric fill layer 342 may be formed of any suitable dielectric material. For example, the second dielectric fill layer 342 may include, but is not limited to silicon dioxide, silicon nitride, silicon oxynitride, high-k materials, polysilicon, spin-on glass, boron phosphosilicate glass, or combinations thereof. The second dielectric fill layer 342 may be formed by any suitable deposition process, including, but not limited to, PVD, CVD, ALD, or any combination thereof. The deposition process may include intermediary steps such as cleaning, degassing, lithography, etching, CMP, or other processes common to semiconductor device manufacturing. The device substrate 300, after operation 232 of method 200, is depicted in FIG. 3P.

At operation 234 of method 200, the dummy-gate material of vertical structures 326, along with the second oxide layer 332, are removed and replaced by a replacement metal gate (RMG) 344. The process forming the RMG 344 at operation 234 generally includes the deposition of the channel dielectric which is typically a chemical oxide selectively deposited on the silicon channel and a conformal high K dielectric material, such as HfO₂. Following these processes, the RMG metal liner and metal fill processes are performed. At the end of operation 234, a metal chemical mechanical polishing process is performed to remove the deposition overburden, forming the individual metal gates. In addition, prior to the dielectric layer deposition steps, the high K dielectric material is doped with the appropriate dipole materials (typically, Al for p-type and La for n-type). RMG 344 may include any suitable conductive material including, but not limited to, cobalt (Co), tungsten (W), ruthenium (Ru), copper (Cu), molybdenum (Mo), titanium (Ti), nickel (Ni), silver (Ag), gold (Au), iridium (Ir), tantalum (Ta), platinum (Pt), conductive oxides or nitrides thereof, or any combination thereof. The RMG 344 may be separated by from the other structures/regions of the device substrate 300 by one or more insulating layers. In some embodiments, the RMG 344 may include multiple layers of the same, or different, conductive materials. Forming the RMG 344 includes several sub processes, such as selectively etching the second oxide layer 332, and depositing the RMG 344.

Selectively etching the second oxide layer 332 of the device substrate 300 may be accomplished through a dry etching process, a wet etching process, or a combination of processes. The selective etching process provides selective removal of the dummy gate (polysilicon). The dry etching process may include plasma etching the device substrate 300. During the dry etching process, a plasma of reactive gases is used to react with and remove the second oxide layer 332 from the top device structure 304A. The reactive gases used in the dry etching process typically include fluorine-based compounds. The high-energy ions and radicals in the plasma break the second oxide layer 332 into volatile byproducts, which are pumped away. In one embodiment, the dry etching process may be highly selective, only removing small portions of the second oxide layer 332. In other embodiments, the dry etching process may be less selective to remove additional material. The dry etching process may include reactive ion etching (RIE), inductively coupled plasma (ICP), capacitively coupled plasma (CCP), or other suitable dry etching process. The wet etching process may include cleaning the device substrate 300, masking portions of the device substrate 300, immersion in an etchant, cleaning, and mask removal. Examples of the etchant used in the wet etching process may include, but are not limited to, potassium hydroxide (KOH), tetramethylammonium hydroxide (TMAH), hydrofluoric acid (HF), buffered oxide etchants such as a mixture of ammonium fluoride (NH₄F) and HF, phosphoric acid (H₃PO₄) nitric acid (HNO₃), acetic acid (CH₃COOH), hydrochloric acid (HCl), ammonium persulfate (NH₄S₂O₈), ferric chloride (FeCl₃), cupric chloride (CuCl₂), acetone, hydrogen peroxide (H₂O₂), deionized water, or any combination thereof. The specific etchant used a wet etching process will depend on the material to be etched. When exposed to the etchant, the second oxide layer 332 being etched is dissolved and becomes part of the soluble solution, which is then removed leaving behind the etched pattern.

The RMG 344 may be formed by any suitable deposition process, including, but not limited to, CVD, PVD, ALD, or any combination thereof. Depositing the RMG 344 may include intermediary steps such as cleaning, degassing, lithography, etching, CMP, or other processes common to semiconductor device manufacturing. The device substrate 300, after operation 234 of method 200, is depicted in FIG. 3Q.

At operation 236 of method 200, a second substrate layer 350 (e.g., a carrier substrate) is bonded to the top surface of the device substrate 300, and then the device substrate 300 is inverted making the first substrate layer 302 the top most portion of the device substrate. The second substrate layer 350 is also a temporary substrate, as it is removed later in the fabrication sequence. The second substrate layer 350 may be bonded to the device substrate 300 by any suitable means and process including, but no limited to, adhesive bonding, thermocompression bonding, anodic bonding, direct bonding (e.g., cold/contact welding), wafer/fusion bonding, solder bonding, plasma-activated bonding, or any combination thereof. The device substrate 300, after operation 236 of method 200, is depicted in FIG. 3R.

At operation 238 of method 200, the first substrate layer 302 and portions of the STI features 312 are removed up to about the isolation structures 330 of the bottom device structure 304B, exposing part of the bottom device structure 304B. Removal of the first substrate layer 302 and portions of the STI features 312 may be performed by any suitable dry etching process, wet etching process, CMP, ion milling, or any combination thereof, as described above. The device substrate 300, after operation 238 of method 200, is depicted in FIG. 3S.

At operation 240 of method 200, the first dielectric fill layer 336, disposed in between the vertical structures 326, in the high-aspect ratio trenches, running perpendicular to the second structure 314B is removed. Removal of the first dielectric fill layer 336 is selective to the isolation structure 330. Following the removal of the first dielectric fill layer 336, a directional dielectric material 337 is deposited such that it is preferentially deposited on top of the vertical structures 326 and at the bottom of the space formed from the removal of the first dielectric fill layer 336. This protects the dummy gate vertical feature during the subsequent epitaxial deposition process. Removal of the first dielectric fill layer 336 may be accomplished by any suitable dry etching process, wet etching process, CMP, or any combination thereof, as described above. The device substrate 300, after operation 240 of method 200, is depicted in FIG. 3T.

At operation 242 of method 200, a p-type material 352 is formed over the bottom device structure 304B. The p-type material 352 is formed via an epitaxy process. Epitaxy generally includes positioning the device substrate 300 on a substrate support in a processing volume of a processing chamber, heating the device substrate 300 to a target temperature, and flowing one or more precursor gases into the processing volume. The precursor gas is selected dependent upon the specific materials and process involved. The precursor gas is selected dependent upon the specific materials and process involved. In one embodiment, the precursor gases may include, but are not limited to, silane (SiH₄), disilane (Si₂H₆), tetrasilane (Si₄H₁₀), germane (GeH₄), digermane (Ge₂H₆), germanium tetrachloride (GeCl₄), trimethylgallium gallium Ga(CH₃)₃, phosphine (PH₃), phosphorus trichloride (PCl₃), triisobutylphosphine ([(CH₃)₃C]₃P), arsenic trichloride (AsCl₃), tertiarybutylarsine (AsC₄H₁₁), antimony trichloride (SbCl₃), or Sb(C₂H₅)₅, Arsine (AsH₃), Diborane (B₂H₆), trimethylphosphine (TMP), or any dopant or precursor common to semiconductor device manufacturing. When heated, the precursor gases decompose and deposit onto the substrate surface first by nucleation, then growth of the crystal lattice structure. By controlling the growth conditions, including temperature, pressure, and precursor gas composition, the proprieties of the resulting epitaxial layer can be controlled. In some embodiments with the p-type device on top, instead of a p-type semiconductor, an n-type semiconductor may be formed in the location of the p-type material 352. The device substrate 300, after operation 242 of method 200, is depicted in FIG. 3U.

At operation 244 of method 200, a second contact etch stop liner (CESL) 354 is formed, and a third dielectric fill layer 356 is disposed. The device substrate 300, after operation 244 of method 200, is depicted in FIG. 3V. The second CESL 354 is disposed on the exposed surfaces of the device substrate 300 including the side surfaces of the vertical structures 326, the top surface of the first dielectric fill layer 336, exposed surfaces of the silicon nitride layer 320, and exterior surfaces of the p-type material 352. The second CESL 354 is a thin layer of material designed to serve as a stop layer during later etching processes. The second CESL 354 may be formed of any suitable material including, but not limited to, silicon nitride, silicon-rich silicon nitride, or any combination thereof. Forming the second CESL 354 may be performed by any suitable deposition process, including, but not limited to, CVD, PVD, ALD, or any combination thereof. The deposition process may include intermediary steps such as cleaning, degassing, lithography, etching, CMP, or other processes common to semiconductor device manufacturing.

Following the second CESL 354, a third dielectric fill layer 356 is disposed over the device substrate 300 filling the remaining areas between the vertical structures 326, covering the p-type material 352 of the bottom device structure 304B. The third dielectric fill layer 356 may be formed of any suitable dielectric material. For example, the third dielectric fill layer 356 may include, but is not limited to silicon dioxide, silicon nitride, silicon oxynitride, high-k materials, polysilicon, spin-on glass, boron phosphosilicate glass, or combinations thereof. The third dielectric fill layer 356 may be formed by any suitable deposition process, including, but not limited to, PVD, CVD, ALD, or any combination thereof. The deposition process may include intermediary steps such as cleaning, degassing, lithography, etching, CMP, or other processes common to semiconductor device manufacturing. For example, a chemical mechanical polish process is performed after the second dielectric fill 356 is formed to remove the excess deposited materials and expose the dummy gate material of vertical structures 326. The device substrate 300, after operation 244 of method 200, is depicted in FIG. 3V.

At operation 246 of method 200, the dummy-gate material of vertical structures 326, along with the second oxide layer 332 and the bottom isolation structure 330 in the bottom device structure 304B, are removed and replaced by a replacement metal gate (RMG) 358. The RMG 358 formation process at operation 246 generally includes the deposition of the channel dielectric which is typically a chemical oxide selectively deposited on the silicon channel and a conformal high K dielectric material, such as HfO₂. Following these processes, the RMG metal liner and metal fill processes are performed. The end of operation 234, a metal chemical mechanical polish process is preformed to remove the deposition overburden, forming the individual metal gates. In addition, prior to the dielectric layer deposition, the high K dielectric material is doped with the appropriate dipole materials (typically, Al for p-type and La for n-type). The RMG 358 may include any suitable conductive material including, but not limited to, cobalt (Co), tungsten (W), ruthenium (Ru), copper (Cu), molybdenum (Mo), titanium (Ti), nickel (Ni), silver (Ag), gold (Au), iridium (Ir), tantalum (Ta), platinum (Pt), conductive oxides or nitrides thereof, or any combination thereof. The RMG 358 may be separated by from the other structures/regions of the device substrate 300 by one or more insulating layers. In some embodiments, the RMG 358 may include multiple layers of the same, or different, conductive materials. Forming the RMG 358 includes several sub processes, such as selectively etching the second oxide layer 332, and depositing the RMG 358.

Selectively etching the second oxide layer 332 of the device substrate 300 may be accomplished through a dry etching process, a wet etching process, or a combination of processes as described above. The selective etching process provides selective removal of the dummy gate (polysilicon) and the bottom isolation structure 330. The RMG 358 may be formed by any suitable deposition process, including, but not limited to, CVD, PVD, ALD, or any combination thereof. Depositing the RMG 344 may include intermediary steps such as cleaning, degassing, lithography, etching, CMP, or other processes common to semiconductor device manufacturing. The device substrate 300, after operation 246 of method 200, is depicted in FIG. 3W.

At operation 248 of method 200, the backside device contacts 360B are formed. Operation 248 may be any suitable contact formation sequence, which in one example generally includes a patterning step to lithographically pattern the contact, etch steps to remove material and open the contacts to the structure (source-drain or gate), silicide step to form an ohmic contact to the source-drain, a metal liner deposition and metal fill step followed by a chemo-mechanical polish step to remove excess deposited material and planarize the structure. The backside device contacts 360B may include the deposition of one or more: passivation layers, metal layers, back side interconnects, and similar structures, or any combination thereof. The backside device contacts 360B may be formed by any suitable process described above. The device substrate 300, after operation 248 of method 200, is depicted in FIG. 3X.

At operation 250 (FIG. 3Y) of method 200, the device substrate 300 is bonded to a third substrate layer 362 (e.g., a backside interconnect substrate assembly). The third substrate layer 362 may be separately fabricated to provide wiring interconnects, suitable for the designed purpose, by any suitable technique. The third substrate layer 362 may include the deposition of one or more: passivation layers, backside metal layers, back side local wiring, backside interconnects, back side vias, devices, structures, or any combination thereof (e.g., bottom device contacts). The third substrate layer 362 may be formed by any suitable process described above. The device substrate 300, after operation 250 of method 200, is depicted in FIG. 3Y.

At operation 252 (FIG. 3Z) of method 200, the second substrate layer 350 is removed, the device substrate 300 is inverted, and the top device contacts 360A are deposited. The top device contacts 360A may include the deposition of one or more: passivation layers, metal layers, frontside interconnects, and similar structures, or any combination thereof. The top device contacts 360A may be formed by any suitable process described above. In one example, the top device contacts 360A may be formed by a conventional or other suitable MOL contact sequence followed by a BEOL interconnect fabrication sequence (only one BEOL interconnect layer is depicted in FIG. 3Z.) The MOL contact sequence typically includes a patterning step to lithographically pattern the contact, etch steps to remove material and open the contacts to the structure (source-drain or gate), silicide step to form an ohmic contact to the source-drain, a metal liner deposition and metal fill step followed by a chemical mechanical polish process to remove excess deposited material and planarize the structure. There are several of these process sequences to form all of the MOL contacts depicted in FIG. 3X. The BEOL sequence is similar to the MOL sequence (except for silicide) and is again a standard process sequence currently in manufacturing. The device substrate 300, after operation 252 of method 200, is depicted in FIG. 3Z

In contrast to a monolithic approach, which relies on complicated alignment and device bonding methods, aspects of the present disclosure include methods allowing for the creation of CFET, or other vertically aligned semiconductor structures, in a more efficient manner utilizing a sequential self-aligning process. The method described herein reduces problems with traditional high-aspect ratio features, by reducing feature height and eliminating several high-aspect ratio modules. Additionally, by inserting another insulator between the nanosheet stacks, the methods described herein, reduce, or eliminate, the requirement for high-temperature thermally stable silicides, contact liners, and gap fill materials allowing allow for current gate-all-around (GAA) replacement metal gate (RMG), and epitaxial, process to be utilized without requiring a lower thermal budget. For example, methods described herein also allow the front copper lines to not be exposed to the backside contact formation thermal budget (≈800-850° C.).

### Additional Considerations

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate. While the various steps in an embodiment method or process are presented and described sequentially, one of ordinary skill in the art will appreciate that some or all of the steps may be executed in different order, may be combined, or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Furthermore, any claimed implementation is considered to be applicable to at least a computer-implemented method; a non-transitory, computer-readable medium storing computer-readable instructions to perform the computer-implemented method; and a computer system including a computer memory interoperability coupled with a hardware processor configured to perform the computer-implemented method or the instructions stored on the non-transitory, computer-readable medium.

As used herein, “a CPU”, “controller”, “a processor”, “at least one processor”, or “one or more processors”, generally refers to a single processor configured to perform one or multiple operations or multiple processors configured to collectively perform one or more operations. In the case of multiple processors, performance the one or more operations could be divided amongst different processors, though one processor may perform multiple operations, and multiple processors could collectively perform a single operation. Similarly, “a memory”, “at least one memory”, or “one or more memories”, generally refers to a single memory configured to store data and/or instructions, multiple memories configured to collectively store data and/or instructions.

As used herein, “gas” and “fluid” may be used interchangeable with either term generally referring to elements, compounds, materials, etc., having the properties of a gas, a fluid, or both a gas and a fluid.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”, “down”, “upward”, “downward,” “horizontal,” “vertical,” and the like do not refer to absolute directions. Instead, these terms refer to directions relative to a nonspecific plane of reference. This non-specific plane of reference may be vertical, horizontal, or other angular orientation.

The singular forms “a”, “an”, and “the”, include plural referents, unless the context clearly dictates otherwise. Within a claim, reference to an element in the singular is not intended to mean “one and only one” unless specifically so stated, but rather “one or more”. Unless specifically stated otherwise, the term “some” refers to one or more.

Embodiments of the present disclosure may suitably “comprise”, “consist”, or “consist essentially of”, the limiting features disclosed, and may be practiced in the absence of a limiting feature not disclosed. As used here and in the appended claims, the words “comprise”, “has”, and “include”, and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

“Coupled” and “coupling” means that the subsequently described material is connected to previously described material. The connection may be a direct, or indirect connection, and may, or may not, include intermediary components such as plumbing, wiring, fasteners, mechanical power transmission, electrical communication, wired and/or wireless transmission, etc., which may suitable to affect operation of the components.

As used, the term “determining” encompasses a wide variety of actions. For example, “determining” may include calculating, computing, processing, deriving, investigating, looking up, for example, looking up in a table, a database, or another data structure, and ascertaining. In addition, “determining” may include receiving, for example, receiving information, and accessing, for example, accessing data in a memory. In addition, “determining” may include resolving, selecting, choosing, and establishing.

When the word “approximately” or “about” are used, this term may mean that there may be a variance in value of up to ±10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. It is the express intention of the applicant not to invoke 35 U.S.C. § 112(f), for any limitations of any of the claims, except for those in which the claim expressly uses the words ‘means for’ together with an associated function.

The methods described herein reduces problems with traditional high-aspect ratio features, by reducing feature height and eliminating several high-aspect ratio modules. Additionally, by inserting another insulator between the nanosheet stacks, the methods described herein, reduce, or eliminate, the requirement for high-temperature thermally stable silicides, contact liners, and gap fill materials allowing allow for current gate-all-around (GAA) replacement metal gate (RMG), and epitaxial, process to be utilized without requiring a lower thermal budget.

The above described technology may be expressed by the following non-limiting examples.

Example 1. A method of forming a complementary field-effect transistor (CFET), including: replacing top sacrificial layers interleaved between channel layers in a top superlattice of a top device structure with top replacement metal gate layers, the top device structure disposed on a bottom device structure, the bottom device structure disposed on a first substrate layer; securing a second substrate layer to the top device structure and removing the first substrate layer from the bottom device structure; and replacing bottom sacrificial layers interleaved between channel layers in a bottom superlattice of the bottom device structure with bottom replacement metal gate layers.

Example 2. The method of Example 1 further including: forming backside device contacts on a side of the bottom device structure opposite from the top device structure.

Example 3. The method of Example 2 further including: securing a third substrate layer to the backside device contacts formed on bottom device structure and removing the second substrate layer from the top device structure.

Example 4. The method of Example 3 further including: forming frontside device contacts on a side of the top device structure opposite from the bottom device structure.

Example 5. The method of Example 1, wherein replacing the top sacrificial layers interleaved between the channel layers in the top superlattice further includes: etching a material of the top sacrificial layers at an etch rate ratio to a material of the channel layers of about 10:1 to about 500:1.

Example 6. The method of Example 5, wherein the material of the top sacrificial layers a germanium (Ge) concentration between about 10% to about 30%.

Example 7. The method of Example 6, wherein the material of the channel layers is one of pure silicon (Si), germanium (Ge), or silicon germanium (SiGe).

Example 8. The method of Example 1 further including: forming vertical structures through the top device structure and the bottom device structure.

Example 9. The method of Example 8 further including: depositing n-type material between the vertical structures formed in the top device structure.

Example 10. The method of Example 8 further including: depositing p-type material between vertical structures formed in the bottom device structure.

Example 11. The method of Example 8, wherein forming the vertical structures through the top device structure and the bottom device structure is performed using a self-aligning process.

Example 12. The method of Example 1, wherein replacing the bottom sacrificial layers interleaved between the channel layers in the bottom superlattice of the bottom device structure is performed at temperatures below about 900 degrees Celsius.

Example 13. A method of forming a complementary field-effect transistor (CFET), including: forming a bottom device structure on a device substrate, wherein the device substrate includes a first substrate layer, wherein the bottom device structure is disposed above the first substrate layer; the bottom device structure including: a sacrificial superlattice layer; a plurality of channel layers disposed over the sacrificial superlattice layer, wherein the plurality of channel layers extend through a dummy gate layer, and the plurality of channel layers are separated by a plurality of sacrificial layers; forming a top device structure, wherein the top device structure is disposed above the bottom device structure; the top device structure including: a sacrificial superlattice layer; a plurality of channel layers disposed over the sacrificial superlattice layer, wherein the plurality of channel layers extend through a dummy gate layer, and the plurality of channel layers are separated by a plurality of sacrificial layers; replacing the sacrificial superlattice layer of the bottom device structure with an isolation structure, and the sacrificial superlattice layer of the top device structure with an isolation structure; disposing a first dielectric fill layer over the bottom device structure; forming an N-channel metal-oxide semiconductor (NMOS) device from the top device structure, wherein forming the NMOS device includes: removing the plurality of sacrificial layers from the top device structure; performing an epitaxial (epi) process to form an n-type source-drain region on at least one exposed surface of the plurality of channel layers of the top device structure; performing a replacement metal gate (RMG) process to replace the dummy gate layer of the top device structure with a metal gate; and disposing a second dielectric fill layer over the NMOS device; bonding a second substrate layer over the NMOS device; removing the first substrate layer; removing the first dielectric fill layer; forming a P-channel metal-oxide semiconductor (PMOS) device from the bottom device structure, wherein forming the PMOS device includes: removing the plurality of sacrificial layers from the bottom device structure; performing an epitaxial process to form p-type source/drain region on region on at least one exposed surface of the plurality of channel layers of the bottom device structure; performing a RMG process to replace the dummy gate layer of the bottom device structure with a metal gate; and disposing a third dielectric fill layer over the PMOS device; forming backside device contacts over the PMOS device; bonding a third substrate layer over the backside device contacts; removing the second substrate layer; and forming frontside device contacts over the NMOS device.

Example 14. The method of Example 13, wherein sequentially forming a CFET device includes a self-aligning process.

Example 15. The method of Example 13, wherein sequentially forming the PMOS device occurs at temperatures below about 900° C.

Example 16. The method of Example 13, wherein: the plurality of channel layers comprise a first material; the plurality of sacrificial layers comprise a second material, wherein: a ratio of an etch rate of the second material to an etch rate of the first material is between about 10:1 to about 500:1, and the second material includes a germanium (Ge) concentration between about 10% to about 30%; and the sacrificial superlattice layers comprise a third material, wherein: a ratio of an etch rate of the third material to the etch rate of the second material and the etch rate of the first material is between about 10:1 to about 200:1, and the third material includes a germanium (Ge) concentration between about 35% to about 60%.

Example 17. A method of forming a complementary field-effect transistor (CFET), including: forming a bottom device structure on a device substrate, wherein the device substrate includes a first substrate layer, wherein the bottom device structure is disposed above the first substrate layer; the bottom device structure including: a sacrificial superlattice layer; a plurality of channel layers disposed over the sacrificial superlattice layer, wherein the plurality of channel layers extend through a dummy gate layer, and the plurality of channel layers are separated by a plurality of sacrificial layers; forming a top device structure, wherein the top device structure is disposed above the bottom device structure; the top device structure including: a sacrificial superlattice layer; a plurality of channel layers disposed over the sacrificial superlattice layer, wherein the plurality of channel layers extend through a dummy gate layer, and the plurality of channel layers are separated by a plurality of sacrificial layers; replacing the sacrificial superlattice layer of the bottom device structure with an isolation structure, and the sacrificial superlattice layer of the top device structure with an isolation structure; disposing a first dielectric fill layer over the bottom device structure; forming an P-channel metal-oxide semiconductor (PMOS) device from the top device structure, wherein forming the PMOS device includes: removing the plurality of sacrificial layers from the top device structure; performing an epitaxial (epi) process to form an p-type source-drain region on at least one exposed surface of the plurality of channel layers of the top device structure; performing a replacement metal gate (RMG) process to replace the dummy gate layer of the top device structure with a metal gate; and disposing a second dielectric fill layer over the PMOS device; bonding a second substrate layer over the PMOS device; removing the first substrate layer; removing the first dielectric fill layer; forming a N-channel metal-oxide semiconductor (NMOS) device from the bottom device structure, wherein forming the NMOS device includes: removing the plurality of sacrificial layers from the bottom device structure; performing an epitaxial process to form n-type source/drain region on region on at least one exposed surface of the plurality of channel layers of the bottom device structure; performing a RMG process to replace the dummy gate layer of the bottom device structure with a metal gate; and disposing a third dielectric fill layer over the NMOS device; forming backside device contacts over the NMOS device; bonding a third substrate layer over the backside device contacts; removing the second substrate layer; and forming frontside device contacts over the PMOS device.

Example 18. The method of Example 17, wherein sequentially forming a CFET device includes a self-aligning process.

Example 19. The method of Example 17, wherein sequentially forming the NMOS device occurs at temperatures below about 900° C.

Example 20. The method of Example 17, wherein: the plurality of channel layers comprise a first material; the plurality of sacrificial layers comprise a second material, wherein: a ratio of an etch rate of the second material to an etch rate of the first material is between about 10:1 to about 500:1, and the second material includes a germanium (Ge) concentration between about 10% to about 30%; and the sacrificial superlattice layers comprise a third material, wherein: a ratio of an etch rate of the third material to the etch rate of the second material and the etch rate of the first material is between about 10:1 to about 200:1, and the third material includes a germanium (Ge) concentration between about 35% to about 60%.

21. A method of forming a complementary field-effect transistor (CFET), including: sequentially forming a CFET device from a nanosheet stack disposed on a first substrate layer, wherein the nanosheet stack includes a bottom device structure and a top device structure disposed over the bottom device structure, the bottom device structure and the top device structure each including: a sacrificial superlattice layer, and a superlattice disposed over the sacrificial superlattice layer, the superlattice including a plurality of channel layers extending through a dummy gate layer, wherein the plurality of channel layers are separated by a plurality of sacrificial layers, wherein the dummy gate layer includes a top dummy gate layer in the top device structure and a bottom dummy gate layer in the bottom device structure, and wherein sequentially forming a CFET device further includes: forming a first portion of a bottom field effect transistor (FET) from the bottom device structure, and forming a first portion of a top FET from the top device structure; replacing the sacrificial superlattice layer of the bottom device structure with an isolation structure, and replacing the sacrificial superlattice layer of the top device structure with an isolation structure; forming a second portion of the bottom FET from the bottom device structure, disposing a first dielectric fill layer over the bottom device structure; forming a second portion of the top FET; bonding a second substrate layer to the top FET; removing the first substrate layer; removing the first dielectric fill layer; forming a second portion of the bottom FET; forming bottom FET device contacts; bonding a third substrate layer to the bottom FET; and forming top FET device contacts.

Example 22. The method of Example 21, wherein sequentially forming a CFET device includes a self-aligning process.

Example 23. The method of Example 21, wherein sequentially forming the second portion of the bottom FET occurs at temperatures below about 900° C.

Example 24. The method of Example 21, wherein: the plurality of channel layers comprise a first material; the plurality of sacrificial layers comprise a second material, wherein: a ratio of an etch rate of the second material to an etch rate of the first material is between about 10:1 to about 500:1, and the second material includes a germanium (Ge) concentration between about 10% to about 30%; and the sacrificial superlattice layer includes a third material, wherein: a ratio of an etch rate of the third material to the etch rate of the second material and the etch rate of the first material is between about 10:1 to about 200:1, and the third material includes a germanium (Ge) concentration between about 35% to about 60%.

Example 25. The method of Example 21, wherein the top FET is an N-channel metal-oxide semiconductor (NMOS) FET, and the bottom FET is a P-channel metal-oxide semiconductor (PMOS) FET.

Example 26. The method of Example 21, wherein the top FET is an P-channel metal-oxide semiconductor (PMOS) FET, and the bottom FET is a N-channel metal-oxide semiconductor (NMOS) FET.

Example 27. The method of Example 21, wherein forming the first portion of the bottom FET and the first portion of the top FET further includes: forming one or more first structures, wherein: each first structure of the one or more first structures include a portion of top device structure disposed over a portion of the bottom device structure, each first structure of the one or more first structures is isolated from each other, and each first structure of the one or more first structures are oriented in a first direction; forming shallow trench isolation (STI) features in the first substrate layer between each first structure of the one or more first structures; disposing a first oxide layer over one or more first structures, and the STI features; disposing a bottom dummy gate layer above the first oxide layer, between each first structure of the one or more first structures, to about the sacrificial superlattice layer of the top device structure; disposing a silicon nitride layer over the bottom dummy gate layer and one or more exposed surfaces of the first oxide layer; disposing a top dummy gate layer above the silicon nitride layer to above the top device structure; forming one or more vertical features, wherein: each vertical feature of the one or more vertical features include a portion of top device structure disposed over a portion of the bottom device structure, each vertical feature of the one or more vertical features isolated from each other, and each vertical feature of the one or more vertical features are oriented perpendicular to the first direction; disposing a spacer layer on one or more exposed side surfaces of the one or more vertical features; recessing the plurality of channel layers, wherein recessing the plurality of channel layers removes a portion of each channel layer of the plurality of channel layers creating a plurality of channel layer voids; selectively etching the sacrificial layers, leaving a plurality of sacrificial layer voids; disposing a second oxide layer in the plurality of sacrificial layer voids; and disposing an inner spacer in the plurality of channel layer voids.

Example 28. The method of Example 21, wherein replacing the sacrificial superlattice layer of the bottom device structure with an isolation structure, and the sacrificial superlattice layer of the top device structure with an isolation structure includes: selectively etching the sacrificial superlattice layers, leaving one or more voids; and disposing the isolation structure in the one or more voids.

Example 29. The method of Example 21, wherein forming a second portion of the top FET further includes: performing an epitaxial (epi) process to form a source/drain (S/D) region on at least one exposed surface of the plurality of channel layers of the top device structure; disposing a first contact etch stop liner (CESL) over the exposed surfaces of the first dielectric fill layer, side surfaces of each vertical feature of one or more vertical features, and the S/D region, wherein: each vertical feature of the one or more vertical features include a portion the top device structure disposed over a portion of the bottom device structure, and each vertical feature of the one or more vertical features is isolated from each other vertical feature; disposing a second dielectric fill layer over the first CESL and between the one or more vertical features; and forming a replacement metal gate (RMG) from the top dummy gate layer.

Example 30. The method of Example 21, wherein forming a second portion of the bottom FET further includes: performing an epitaxial (epi) process to form a source/drain (S/D) region on at least one exposed surface of the plurality of channel layers of the bottom device structure; disposing a second contact etch stop liner (CESL) over the exposed surfaces of the top device structure, side surfaces of each vertical feature of one or more vertical features, and the S/D region, wherein: each vertical feature of the one or more vertical features include a portion the bottom device structure disposed over a portion of the bottom device structure, and each vertical feature of the one or more vertical features is isolated from each other vertical feature; disposing a third dielectric fill layer over a first CESL and between the one or more vertical features; and forming a replacement metal gate (RMG) from the bottom dummy gate layer.

The following claims are not intended to be limited to the embodiments provided but rather are to be accorded the full scope consistent with the language of the claims.

What is claimed is:

1. A method of forming a complementary field-effect transistor (CFET), comprising:
replacing top sacrificial layers interleaved between channel layers in a top superlattice of a top device structure with top replacement metal gate layers, the top device structure disposed on a bottom device structure, the bottom device structure disposed on a first substrate layer;
securing a second substrate layer to the top device structure and removing the first substrate layer from the bottom device structure; and
replacing bottom sacrificial layers interleaved between channel layers in a bottom superlattice of the bottom device structure with bottom replacement metal gate layers.

2. The method of claim 1 further comprising:
forming backside device contacts on a side of the bottom device structure opposite from the top device structure.

3. The method of claim 2 further comprising:
securing a third substrate layer to the backside device contacts formed on bottom device structure and removing the second substrate layer from the top device structure.

4. The method of claim 3 further comprising:
forming frontside device contacts on a side of the top device structure opposite from the bottom device structure.

5. The method of claim 1, wherein replacing the top sacrificial layers interleaved between the channel layers in the top superlattice further comprises:
etching a material of the top sacrificial layers at an etch rate ratio to a material of the channel layers of about 10:1 to about 500:1.

6. The method of claim 5, wherein the material of the top sacrificial layers a germanium (Ge) concentration between about 10% to about 30%.

7. The method of claim 6, wherein the material of the channel layers is one of pure silicon (Si), germanium (Ge), or silicon germanium (SiGe).

8. The method of claim 1 further comprising:
forming vertical structures through the top device structure and the bottom device structure.

9. The method of claim 8 further comprising:
depositing n-type material between the vertical structures formed in the top device structure.

10. The method of claim 8 further comprising:
depositing p-type material between vertical structures formed in the bottom device structure.

11. The method of claim 8, wherein forming the vertical structures through the top device structure and the bottom device structure is performed using a self-aligning process.

12. The method of claim 1, wherein replacing the bottom sacrificial layers interleaved between the channel layers in the bottom superlattice of the bottom device structure is performed at temperatures below about 900 degrees Celsius.

13. A method of forming a complementary field-effect transistor (CFET), comprising:
forming a bottom device structure on a device substrate, wherein the device substrate comprises a first substrate layer, wherein the bottom device structure is disposed above the first substrate layer; the bottom device structure comprising:
a sacrificial superlattice layer;
a plurality of channel layers disposed over the sacrificial superlattice layer, wherein the plurality of channel layers extend through a dummy gate layer, and the plurality of channel layers are separated by a plurality of sacrificial layers;
forming a top device structure, wherein the top device structure is disposed above the bottom device structure; the top device structure comprising:
a sacrificial superlattice layer;
a plurality of channel layers disposed over the sacrificial superlattice layer, wherein the plurality of channel layers extend through a dummy gate layer, and the plurality of channel layers are separated by a plurality of sacrificial layers;
replacing the sacrificial superlattice layer of the bottom device structure with an isolation structure, and the sacrificial superlattice layer of the top device structure with an isolation structure;
disposing a first dielectric fill layer over the bottom device structure;
forming an N-channel metal-oxide semiconductor (NMOS) device from the top device structure, wherein forming the NMOS device comprises:
removing the plurality of sacrificial layers from the top device structure;
performing an epitaxial (epi) process to form an n-type source-drain region on at least one exposed surface of the plurality of channel layers of the top device structure;
performing a replacement metal gate (RMG) process to replace the dummy gate layer of the top device structure with a metal gate; and
disposing a second dielectric fill layer over the NMOS device;
bonding a second substrate layer over the NMOS device;
removing the first substrate layer;
removing the first dielectric fill layer;
forming a P-channel metal-oxide semiconductor (PMOS) device from the bottom device structure, wherein forming the PMOS device comprises:
removing the plurality of sacrificial layers from the bottom device structure;
performing an epitaxial process to form p-type source/drain region on region on at least one exposed surface of the plurality of channel layers of the bottom device structure;
performing a RMG process to replace the dummy gate layer of the bottom device structure with a metal gate; and
disposing a third dielectric fill layer over the PMOS device;
forming backside device contacts over the PMOS device;
bonding a third substrate layer over the backside device contacts;
removing the second substrate layer; and
forming frontside device contacts over the NMOS device.

14. The method of claim 13, wherein sequentially forming a CFET device comprises a self-aligning process.

15. The method of claim 13, wherein sequentially forming the PMOS device occurs at temperatures below about 900° C.

16. The method of claim 13, wherein:
the plurality of channel layers comprise a first material;
the plurality of sacrificial layers comprise a second material, wherein:
a ratio of an etch rate of the second material to an etch rate of the first material is between about 10:1 to about 500:1, and
the second material includes a germanium (Ge) concentration between about 10% to about 30%; and
the sacrificial superlattice layers comprise a third material, wherein:
a ratio of an etch rate of the third material to the etch rate of the second material and the etch rate of the first material is between about 10:1 to about 200:1, and
the third material includes a germanium (Ge) concentration between about 35% to about 60%.

17. A method of forming a complementary field-effect transistor (CFET), comprising:
forming a bottom device structure on a device substrate, wherein the device substrate comprises a first substrate layer, wherein the bottom device structure is disposed above the first substrate layer; the bottom device structure comprising:
a sacrificial superlattice layer;
a plurality of channel layers disposed over the sacrificial superlattice layer, wherein the plurality of channel layers extend through a dummy gate layer, and the plurality of channel layers are separated by a plurality of sacrificial layers;
forming a top device structure, wherein the top device structure is disposed above the bottom device structure; the top device structure comprising:
a sacrificial superlattice layer;
a plurality of channel layers disposed over the sacrificial superlattice layer, wherein the plurality of channel layers extend through a dummy gate layer, and the plurality of channel layers are separated by a plurality of sacrificial layers;
replacing the sacrificial superlattice layer of the bottom device structure with an isolation structure, and the sacrificial superlattice layer of the top device structure with an isolation structure;
disposing a first dielectric fill layer over the bottom device structure;
forming an P-channel metal-oxide semiconductor (PMOS) device from the top device structure, wherein forming the PMOS device comprises:
removing the plurality of sacrificial layers from the top device structure;
performing an epitaxial (epi) process to form an p-type source-drain region on at least one exposed surface of the plurality of channel layers of the top device structure;
performing a replacement metal gate (RMG) process to replace the dummy gate layer of the top device structure with a metal gate; and
disposing a second dielectric fill layer over the PMOS device;
bonding a second substrate layer over the PMOS device;
removing the first substrate layer;
removing the first dielectric fill layer;
forming a N-channel metal-oxide semiconductor (NMOS) device from the bottom device structure, wherein forming the NMOS device comprises:
removing the plurality of sacrificial layers from the bottom device structure;
performing an epitaxial process to form n-type source/drain region on region on at least one exposed surface of the plurality of channel layers of the bottom device structure;
performing a RMG process to replace the dummy gate layer of the bottom device structure with a metal gate; and
disposing a third dielectric fill layer over the NMOS device;
forming backside device contacts over the NMOS device;
bonding a third substrate layer over the backside device contacts;
removing the second substrate layer; and
forming frontside device contacts over the PMOS device.

18. The method of claim 17, wherein sequentially forming a CFET device comprises a self-aligning process.

19. The method of claim 17, wherein sequentially forming the NMOS device occurs at temperatures below about 900° C.

20. The method of claim 17, wherein:
the plurality of channel layers comprise a first material;
the plurality of sacrificial layers comprise a second material, wherein:
a ratio of an etch rate of the second material to an etch rate of the first material is between about 10:1 to about 500:1, and
the second material includes a germanium (Ge) concentration between about 10% to about 30%; and
the sacrificial superlattice layers comprise a third material, wherein:
a ratio of an etch rate of the third material to the etch rate of the second material and the etch rate of the first material is between about 10:1 to about 200:1, and
the third material includes a germanium (Ge) concentration between about 35% to about 60%.
